(19) United States
(12) Patent Application Publication
(10) Pub. No.: US 2025/0385178 A1
(43) Pub. Date: Dec. 18, 2025

(54) BACK END MEMORY ARRAY IN A SEMICONDUCTOR DEVICE AND METHODS OF FORMATION

(71) Applicant: Taiwan Semiconductor Manufacturing Company, Ltd., Hsinchu (TW)

(72) Inventors: Tzu-Yu CHEN, Kaohsiung City (TW); Chia-En HUANG, Xinfeng Township (TW)

(21) Appl. No.: 18/741,096

(22) Filed: Jun. 12, 2024

(51) Int. Cl. H01L 23/528; H10B 53/10; H10B 53/20

(52) U.S. Cl. CPC H01L 23/5283; H01L 23/528; H10B 53/10; H10B 53/20

(57) ABSTRACT

Memory cells in a memory array in an interconnect layer of a semiconductor device may be distributed across a plurality of vertically arranged layers in the interconnect layer. This enables a three-dimensional array of memory cells to be achieved in the interconnect layer of the semiconductor device, which provides a greater amount of lateral area in each metallization layer for the memory cells. This enables a high density of memory cells to be achieved in the memory array without sacrificing the size of the memory cells and/or the spacing between memory cells, which enables more stable operation and a longer operational life for the memory cells.

### BACKGROUND

Many types of semiconductor devices include memory cells. Some types of semiconductor devices include memory cells in an interconnect layer (e.g., a back end region). The memory cells in an interconnect layer of a semiconductor device may support the functions of devices included in a device layer of the semiconductor device, such as on-board memory and cache for the logic devices in the device layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are diagrams of an example semiconductor device described herein.

FIGS. 2A-2I are diagrams of an example implementation of forming a semiconductor device described herein.

FIGS. 3A-3E are diagrams of an example semiconductor device described herein.

FIG. 4 is a diagram of an example semiconductor device described herein.

FIG. 5 is a diagram of an example semiconductor device described herein.

FIG. 6 is a diagram of an example semiconductor device described herein.

FIGS. 7A-7C are diagrams of an example semiconductor device described herein.

FIGS. 8A-8C are diagrams of an example semiconductor device described herein.

FIG. 9 is a diagram of an example memory structure described herein.

FIG. 10 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One of the main goals in the semiconductor industry is to progressively reduce the size of components on a semiconductor device. For example, advancement of semiconductor manufacturing process nodes enables components of a semiconductor device such as transistors and memory cells to be made smaller, thereby achieving greater component density, reduced power consumption, and/or faster operation for the semiconductor device. Reducing the size of memory cells in a semiconductor device may enable a greater density of memory cells in a memory array of the semiconductor device to be achieved. However, decreasing the size of a memory cell may degrade one or more aspects of the performance of the memory cell. For example, decreasing the size of a memory cell may result in unstable operation for the memory cell, which may cause the memory cell to be prone to bit errors and data corruption. As another example, decreasing the size of the layers of a memory cell may reduce the robustness and the lifespan of those layers, making the layer prone to failure and resulting in accelerated wear out for the memory cell.

In some implementations described herein, memory cells in a memory array in an interconnect layer of a semiconductor device may be distributed across a plurality of vertically arranged layers in the interconnect layer. For example, a first subset of memory cells of the memory array may be included in a first layer of conductive structures of the interconnect layer, and a second subset of memory cells of the memory array may be included in a second layer of conductive structures of the interconnect layer above the first layer of conductive structures. This enables a three-dimensional array of memory cells to be achieved in the interconnect layer of the semiconductor device, which provides a greater amount of lateral area in each metallization layer for the memory cells. This enables a high density of memory cells to be achieved in the memory array without sacrificing the size of the memory cells and/or the spacing between memory cells, which enables more stable operation and a longer operational life for the memory cells.

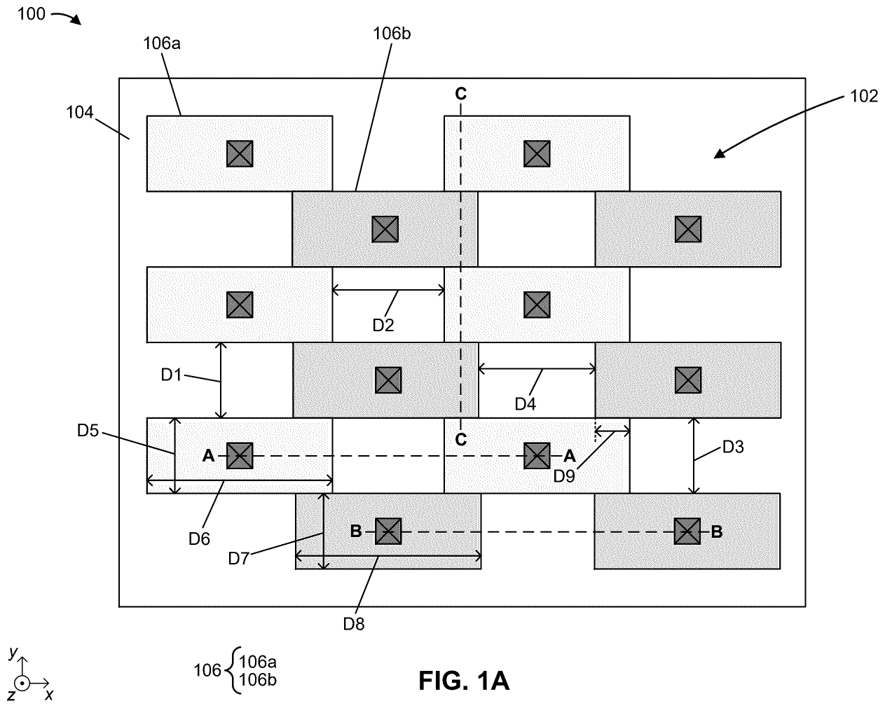

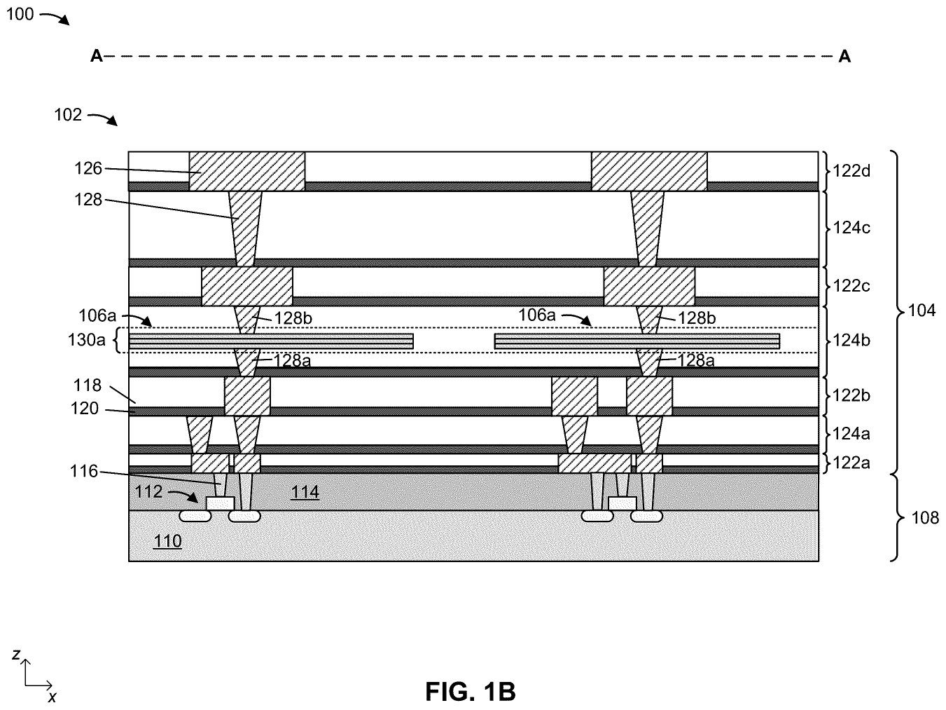

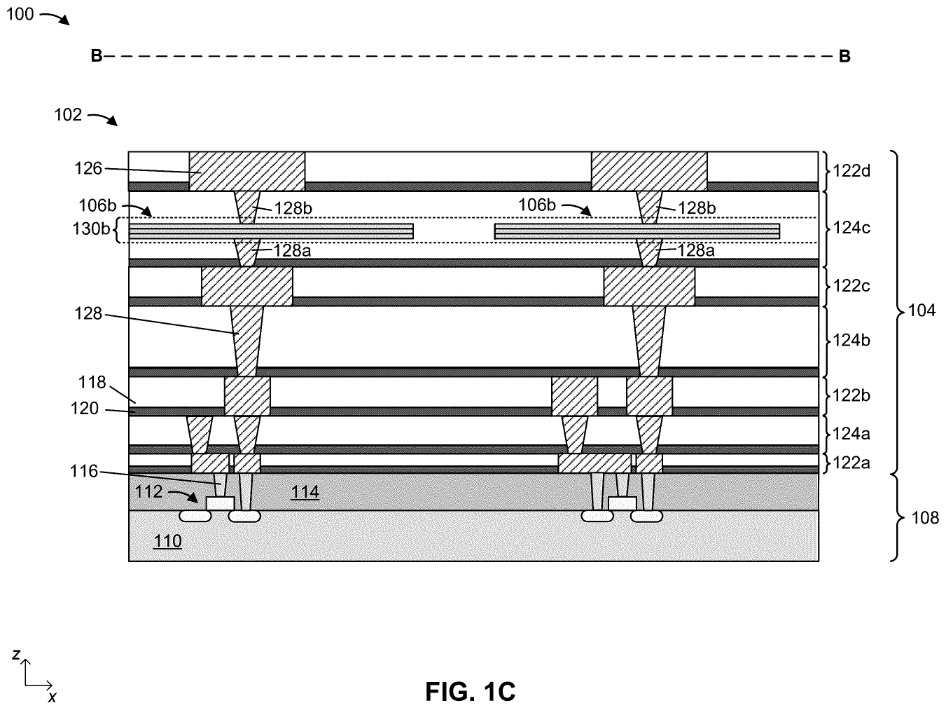

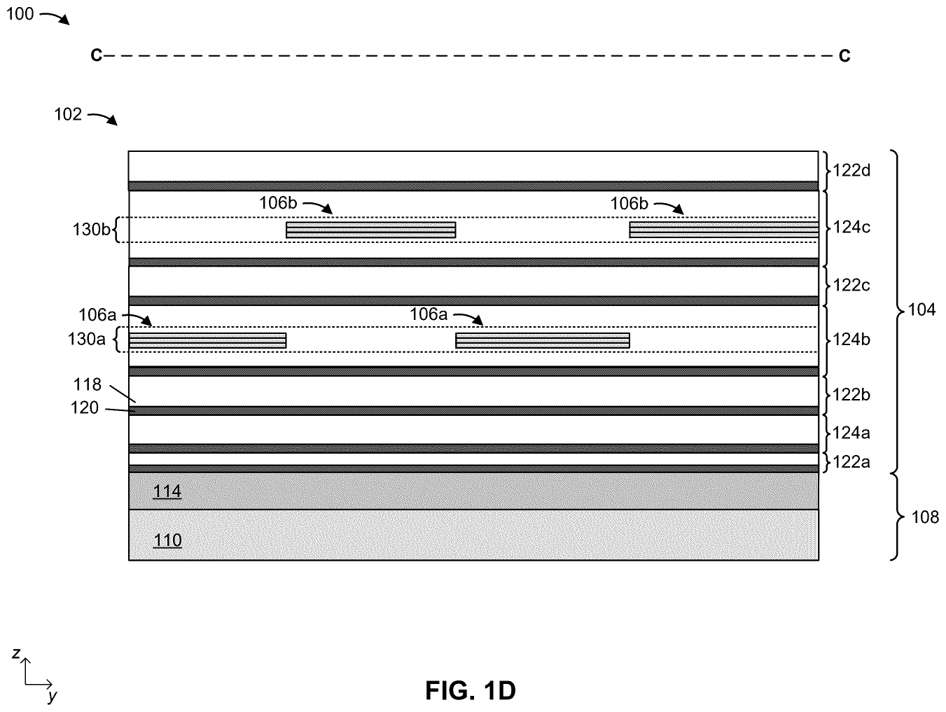

FIGS. 1A-1D are diagrams of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), and/or another type of semiconductor device.

FIG. 1A illustrates a top view of the semiconductor device 100. As shown in FIG. 1A, the semiconductor device 100 includes a memory array 102 in an interconnect layer 104 of the semiconductor device 100. The interconnect layer 104 may also be referred to a back end region or back end of line (BEOL) region of the semiconductor device 100, and may include conductive structures that are arranged to carry signals and/or provide power distribution throughout the semiconductor device 100.

The memory array 102 includes a plurality of memory structures 106 arranged in an array. The memory structures 106 of the memory array 102 may include one or more types of memory structures that are configured to selectively change states corresponding to different logical values. For example, the memory structures 106 may include dynamic random access memory (DRAM) structures, magnetic random access memory (MRAM) structures, resistive random access memory (RRAM) structures, phase-change random access memory (PCRAM) structures, ferroelectric random access memory (FeRAM) structures, floating gate memory structures (e.g., FLASH memory structures), and/or another type of memory structures. A memory structure 106 may store a logical value based on a resistive state of the memory structure 106, based on a charge accumulation state of the memory structure 106, based on a magnetic state of the memory structure 106, based on a polarity of the memory structure 106, and/or based on another property of the memory structure 106.

In some implementations, a memory structure 106 corresponds to a portion of a memory cell of the memory array 102. For example, a memory structure 106 may include a magnetic tunnel junction (MTJ) of an MRAM cell, a ferroelectric tunnel junction (FTJ) of an FeRAM cell, and/or a capacitor structure of a DRAM cell, among other examples. In these implementations, the memory structure 106 may be electrically coupled to a transistor structure of the memory cell in the semiconductor device 100 (e.g., a back end transistor in the interconnect layer 104, a front end transistor in a device layer of the semiconductor device 100) that enables the memory structure 106 to be selected. In some implementations, a memory structure 106 corresponds to a memory cell in which an access mechanism or selecting mechanism is integrated into the memory structure 106. For example, the memory structure 106 may include a floating gate transistor or a ferroelectric field effect transistor (FeFET), among other examples.

As described herein, the arrangement of the memory array 102 is three-dimensional in that the memory structures 106 are arranged in three dimensions in the interconnect layer 104 of the semiconductor device 100, including in an x-direction, in a y-direction, and in a z-direction in the interconnect layer 104. Moreover, as described herein, the memory structures 106 are distributed in vertical layers across a plurality of layers of conductive structures in the interconnect layer 104. For example, a first plurality of memory structures 106a of the memory array 102 may be included in a first layer of conductive structures in the interconnect layer 104, and a second plurality of memory structures 106b of the memory array 102 may be included in a second layer of conductive structures in the interconnect layer 104 above the first layer of conductive structures. The three-dimensional distribution of the memory structures 106 in the interconnect layer 104 enables the memory structures 106 to have a greater size and/or enables greater lateral spacing between memory structures 106 than if the memory structures 106 were arranged in a two-dimensional array in (e.g., only in the x-direction and the y-direction) while achieving a similar or greater memory structure density in the memory array 102.

For example, a y-direction spacing (indicated in FIG. 1A as dimension D1) between adjacent memory structures 106a in the first layer of conductive structures in the interconnect layer 104, and/or an x-direction spacing (indicated in FIG. 1A as dimension D2) between adjacent memory structures 106a in the first layer of conductive structures in the interconnect layer 104, may each be as much as four times greater than the spacing between adjacent memory structures in a two-dimensional arrangement of memory structures in an interconnect layer of a semiconductor device. In some implementations, the x-direction spacing and/or the y-direction spacing between adjacent memory structures 106a is more than four times greater than the spacing between adjacent memory structures in a two-dimensional arrangement of memory structures in an interconnect layer of a semiconductor device.

As another example, a y-direction spacing (indicated in FIG. 1A as dimension D3) between adjacent memory structures 106b in the second layer of conductive structures in the interconnect layer 104, and/or an x-direction spacing (indicated in FIG. 1A as dimension D4) between adjacent memory structures 106b in the second layer of conductive structures in the interconnect layer 104, may each be as much as four times greater than the spacing between adjacent memory structures in a two-dimensional arrangement of memory structures in an interconnect layer of a semiconductor device. In some implementations, the x-direction spacing and/or the y-direction spacing between adjacent memory structures 106b is more than four times greater than the spacing between adjacent memory structures in a two-dimensional arrangement of memory structures in an interconnect layer of a semiconductor device.

As another example, a z-direction spacing between the memory structures 106a in the first layer of conductive structures in the interconnect layer 104 and the memory structures 106b in the second layer of conductive structures in the interconnect layer 104 may be as much as four times greater than the spacing between adjacent memory structures in a two-dimensional arrangement of memory structures in an interconnect layer of a semiconductor device. In some implementations, the z-direction spacing between the memory structures 106a and the memory structures 106b is more than four times greater than the spacing between adjacent memory structures in a two-dimensional arrangement of memory structures in an interconnect layer of a semiconductor device.

As another example, a y-direction width (indicated in FIG. 1A as dimension D5) of the memory structures 106a in the first layer of conductive structures in the interconnect layer 104, and/or an x-direction width (indicated in FIG. 1A as dimension D6) of the memory structures 106a in the first layer of conductive structures in the interconnect layer 104, may each be as much as four times greater than the width of memory structures in a two-dimensional arrangement of memory structures in an interconnect layer of a semiconductor device because of the greater lateral and/or vertical spacing between the memory structures 106a and 106b in the memory array 102. In some implementations, the x-direction width and/or the y-direction width of the memory structures 106a is more than four times greater than the width of memory structures in a two-dimensional arrangement of memory structures in an interconnect layer of a semiconductor device.

As another example, a y-direction width (indicated in FIG. 1A as dimension D7) of the memory structures 106b in the second layer of conductive structures in the interconnect layer 104, and/or an x-direction width (indicated in FIG. 1A as dimension D8) of the memory structures 106b in the second layer of conductive structures in the interconnect layer 104, may each be as much as four times greater than the width of memory structures in a two-dimensional arrangement of memory structures in an interconnect layer of a semiconductor device because of the greater lateral and/or vertical spacing between the memory structures 106a and 106b in the memory array 102. In some implementations, the x-direction width and/or the y-direction width of the memory structures 106b is more than four times greater than the width of memory structures in a two-dimensional arrangement of memory structures in an interconnect layer of a semiconductor device.

As further shown in FIG. 1A, a memory structure 106a may laterally extend past an end or side of a memory structure 106b by a distance (indicated in FIG. 1A as dimension D9) and/or a memory structure 106b may laterally extend past an end or side of a memory structure 106a by a distance (indicated in FIG. 1A as the dimension D9). This is because the memory structures 106a and 106b are included in layers of conductive structures that are located at different vertical (z-direction) heights or in the interconnect layer 104, and the minimum spacing between memory structures 106a and memory structures 106b is maintained in the z-direction in the interconnect layer 104. In some implementations, the dimension D9 is greater than 0 nanometers and less than or approximately equal to 50 nanometers. However, other values and ranges are within the scope of the present disclosure.

FIG. 1B illustrates a cross-section view of the semiconductor device 100 along the line A-A in FIG. 1A. Thus, the cross-section view in FIG. 1B is in the x-z plane in the semiconductor device 100, and is across a plurality of memory structures 106a. As shown in FIG. 1B, the semiconductor device 100 may include a device layer 108. The interconnect layer 104 is located above the device layer 108 in a z-direction in the semiconductor device 100. The device layer 108 may also be referred to as a front end region or front end of line (FEOL) region of the semiconductor device 100.

The device layer 108 includes a substrate 110 of the semiconductor device 100. The substrate 110 may correspond to a portion of a semiconductor wafer on which the semiconductor device 100 is formed. The substrate 110 may include a silicon (Si) substrate, a substrate formed of a material including silicon, a III-V compound semiconductor material substrate such as gallium arsenide (GaAs), a silicon on insulator (SOI) substrate, or another type of substrate. The substrate 110 may extend in the x-direction and/or in the y-direction in the semiconductor device 100.

Integrated circuit devices 112 may be included in and/or on the substrate 110 in the device layer 108 of the semiconductor device 100. The integrated circuit devices 112 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices. In some implementations, the integrated circuit devices 112 are electrically coupled to the memory structures 106 in the memory array 102 to form the memory cells of the memory array 102.

A front end transistor structure may include a plurality of source/drain regions, which may correspond to doped regions of the substrate 110, separated by a channel region in the substrate 110. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 114 is included over the substrate 110. The dielectric layer 114 includes an interlayer dielectric (ILD) layer, an etch stop layer (ESL), and/or another type of portions of the substrate 110 and/or the integrated circuit devices 112 to be selectively etched or protected from etching, and/or to electrically isolate the integrated circuit devices 112 in the device layer 108. The dielectric layer 114 includes a silicon nitride (SiₓN_{y}), an oxide (e.g., a silicon oxide (SiOₓ) and/or another oxide material), and/or another type of dielectric material. The dielectric layer 114 may extend in the x-direction and/or in the y-direction in the semiconductor device 100. Contacts 116 (e.g., source/drain contacts, gate contacts) may be extend through the dielectric layer 114 and between the integrated circuit devices 112 and the interconnect layer 104. The contacts 116 may electrically connect the integrated circuit devices 112 and the interconnect layer 104. The contacts 116 may include vias, plugs, and/or another type of elongated electrically conductive structures. The contacts 116 may include tungsten (W), cobalt (Co), ruthenium (Ru), titanium (Ti), aluminum (Al), and/or gold (Au), among other electrically conductive materials.

The interconnect layer 104 of the semiconductor device 100 is included above the substrate 110 and above the integrated circuit devices 112 in the z-direction in the semiconductor device 100. The interconnect layer 104 includes a plurality of dielectric layers (e.g., back end dielectric layers) that are arranged in a direction (e.g., the z-direction) that is approximately perpendicular to the substrate 110. The dielectric layers may include ILD layers 118 and ESLs 120 that are arranged in an alternating manner in the z-direction. The ILD layers 118 and the ESLs 120 may extend in the x-direction and/or in the y-direction in the semiconductor device 100.

The ILD layers 118 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 118 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples. oxynitride (SiON), and/or another suitable dielectric material. In some implementations, an ILD layer 118 and an ESL 120 include different dielectric materials to provide etch selectivity to enable various structures to be formed in the interconnect layer 104.

The interconnect layer 104 includes a plurality of conductive structures that are arranged in plurality of layers. The conductive structures may be electrically coupled and/or physically coupled with one or more of the integrated circuit devices 112 in the device layer 108. The conductive structures provide electrical routing that enables signals and/or power to be provided to and/or from the integrated circuit devices 112 and/or the memory structures 106 in the interconnect layer 104, among other examples.

The layers of conductive structures may include a plurality of layers 122a-122d that are vertically arranged and alternate with a plurality of layers 124a-124c in the z-direction (e.g., vertically alternate). The layers 122a-122d each include a layer of metallization structures 126, and the layers 124a-124c each include a layer of interconnect structures 128. The layers 122a-122d of metallization structures 126 may be referred to as M-layers. For example, a layer 122a of metallization structures 126 (referred to as a metal-0 (M0) layer) may located at the bottom of the interconnect layer 104 and may be directly coupled with the device layer 108 (e.g., with the contacts 116 of the integrated circuit devices 112 in the device layer 108), a layer 122b of metallization structures 126 (referred to as a metal-1 layer (M1) layer) may be located above the layer 122a of metallization structures 126 in the interconnect layer 104, a layer 122c of metallization structures 126 (referred to as a metal-2 layer (M2) layer) may be located above the a layer 122b of metallization structures 126, and so on. A layer 124a of interconnect structures 128 (referred to as a via-1 (V1) layer) may be included between the M0 layer and the M1 layer to interconnect the M0 layer and the M1 layer, a layer 124b of interconnect structures 128 (referred to as a via-2 (V2) layer) may be included between the M1 layer and the M2 layer to interconnect the M1 layer and the M2 layer, and so on.

The metallization structures 126 may include a combination of trenches, metallization layers, conductive traces, and/or other types of conductive structures. The interconnect structures 128 may include a combination of vias, interconnects, and/or other types of conductive structures. The metallization structures 126 and the interconnect structures 128 may one or more electrically conductive materials such as tungsten (W), cobalt (Co), ruthenium (Ru), titanium examples of electrically conductive materials. In some implementations, one or more liner layers are included between the dielectric layers of the interconnect layer 104 and the metallization structures 126, and/or between the dielectric layers of the interconnect layer 104 the interconnect structures 128. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 126, a topmost layer of interconnect structures 128) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures.

As further shown in FIG. 1B, the memory structures 106a may be included in a memory layer 130a in the interconnect layer 104. The memory layer 130a (and thus, the memory structures 106a included in the memory layer 130a) is located at a first vertical (z-direction) height in the interconnect layer 104 (e.g., relative to the substrate 110, relative to the bottom of the interconnect layer 104) and in a same ILD layer 118 in the interconnect layer 104. In some implementations, two or more memory structures 106a included in the memory layer 130a are located at a same vertical (z-direction) height in the memory layer 130a and are therefore included in a same x-y plane in the interconnect layer 104. In some implementations, two or more memory structures 106a included in the memory layer 130a are located at different vertical (z-direction) heights in the memory layer 130a and are therefore included in different x-y planes in the interconnect layer 104, while still being located in the same ILD layer 118.

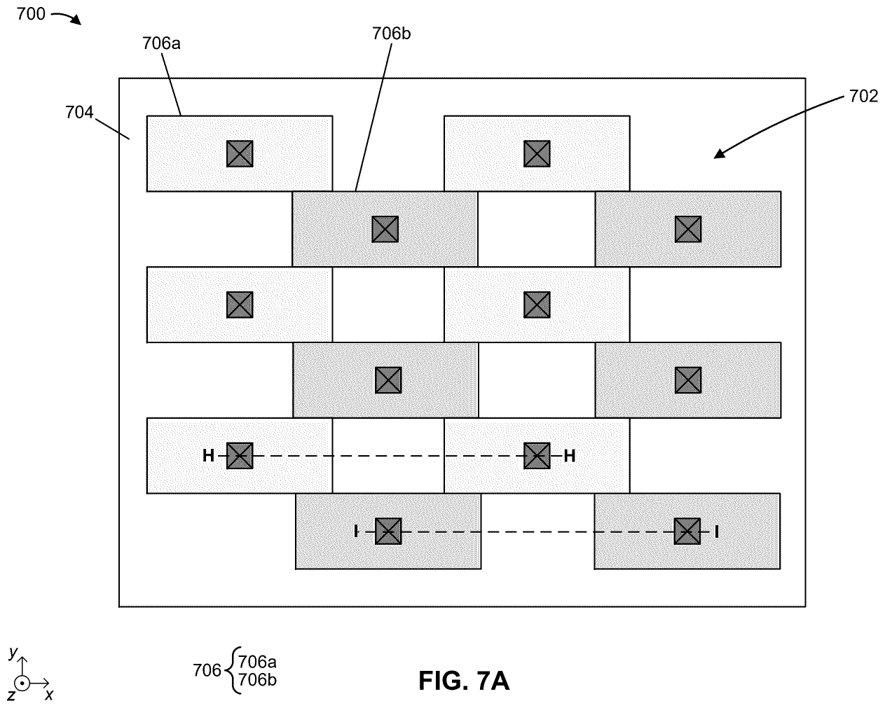

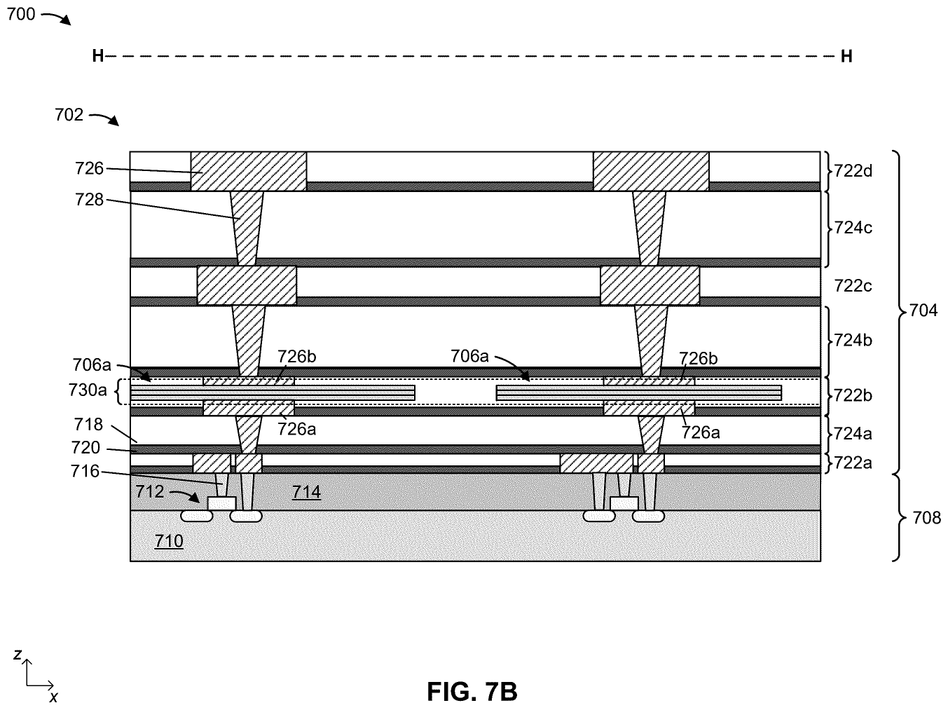

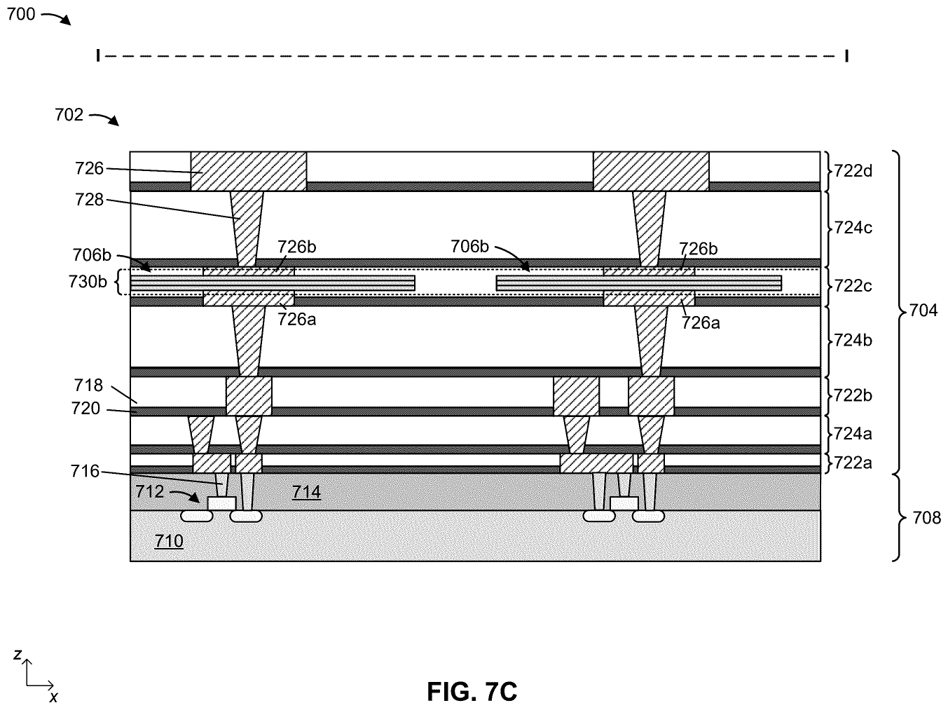

In some implementations, the memory layer 130a (and thus, the memory structures 106a included in the memory layer 130a) is included in a layer of interconnect structures 128, such as the layer 124b as shown in the example in FIG. 1B. However, the memory layer 130a (and thus, the memory structures 106a included in the memory layer 130a) may be included in another layer of interconnect structures 128 in the interconnect layer 104, or may be located in a layer of metallization structures 126 as shown in an example in FIGS. 7A-7C.

In the layer 124b of interconnect structures 128, a memory structure 106a may be electrically coupled and/or physically coupled with interconnect structure 128a at a bottom of the memory structure 106a, and may be electrically coupled and/or physically coupled with interconnect structure 128b at a top of the memory structure 106a. Thus, the interconnect structures 128a and 128b coupled to the memory structure 106a may each vertically span less than the entire vertical (z-direction) height of the layer 124b of interconnect structures 128. The interconnect structures 128a in the layer 124b may be electrically coupled and/or physically coupled with metallization structures 126 in the layer 122b below the layer 124b, and the interconnect structures 128b in the layer 124b may be electrically coupled and/or physically coupled with metallization structures 126 in the layer 122c above the layer 124b.

FIG. 1C illustrates a cross-section view of the semiconductor device 100 along the line B-B in FIG. 1A. Thus, the cross-section view in FIG. 1C is in the x-z plane in the semiconductor device 100, and is across a plurality of memory structures 106b. As shown in FIG. 1C, the memory structures 106b may be included in a memory layer 130b in the interconnect layer 104. The memory layer 130b (and thus, the memory structures 106b included in the memory layer 130b) is located at a second vertical (z-direction) height in the interconnect layer 104 (e.g., relative to the substrate 110, relative to the bottom of the interconnect layer 104) and in a same ILD layer 118 in the interconnect layer 104. In some implementations, two or more memory structures 106b included in the memory layer 130b are located at a same vertical (z-direction) height in the memory layer 130b and are therefore included in a same x-y plane in the interconnect layer 104. In some implementations, two or more memory structures 106b included in the memory layer 130b are located at different vertical (z-direction) heights in the memory layer 130b and are therefore included in different x-y planes in the interconnect layer 104, while still being located in the same ILD layer 118.

In some implementations, the memory layer 130b (and thus, the memory structures 106b included in the memory layer 130b) is included in a layer of interconnect structures 128, such as the layer 124c as shown in the example in FIG. 1C. However, the memory layer 130b (and thus, the memory structures 106b included in the memory layer 130b) may be included in another layer of interconnect structures 128 in the interconnect layer 104, or may be located in a layer of metallization structures 126 as shown in an example in FIGS. 7A-7C.

In the layer 124c of interconnect structures 128, a memory structure 106b may be electrically coupled and/or physically coupled with interconnect structure 128a at a bottom of the memory structure 106b, and may be electrically coupled and/or physically coupled with interconnect structure 128b at a top of the memory structure 106b. Thus, the interconnect structures 128a and 128b coupled to the memory structure 106b may each vertically span less than the entire vertical (z-direction) height of the layer 124c of interconnect structures 128. The interconnect structures 128a in the layer 124c may be electrically coupled and/or physically coupled with metallization structures 126 in the layer 122c below the layer 124c, and the interconnect structures 128b in the layer 124c may be electrically coupled and/or physically coupled with metallization structures 126 in the layer 122d above the layer 124c.

In some implementations, each of the memory structures 106a and each of the memory structure 106b may be electrically coupled with different signal lines (e.g., different vertical arrangements of metallization structures 126 and interconnect structures 128) in the interconnect layer 104. This enables each of the memory structures 106a and each of the memory structure 106b to be individually addressable and accessed in the memory array 102.

FIG. 1D illustrates a cross-section view of the semiconductor device 100 along the line C-C in FIG. 1A. Thus, the cross-section view in FIG. 1D is in the y-z plane in the semiconductor device 100, and is across alternating memory structures 106a and 106b. As shown in FIG. 1D, the second vertical (z-direction) height of the memory layer 130b is greater than the first vertical (z-direction) height of the memory layer 130a. Thus, the memory layer 130b (and thus, the memory structures 106b included in the memory layer 130b) is located above the memory layer 130a (and thus, the memory structures 106a included in the memory layer 130a). This enables the size of the memory structures 106a and/or the spacing between the memory structures 106a to be increased, and/or enables the size of the memory structures 106b and/or the spacing between the memory structures 106b to be increased, while maintaining sufficient z-direction spacing between the memory structures 106a and the memory structures 106b.

As indicated above, FIGS. 1A-1D are provided as an example. Other examples may differ from what is described with regard to FIGS. 1A-1D.

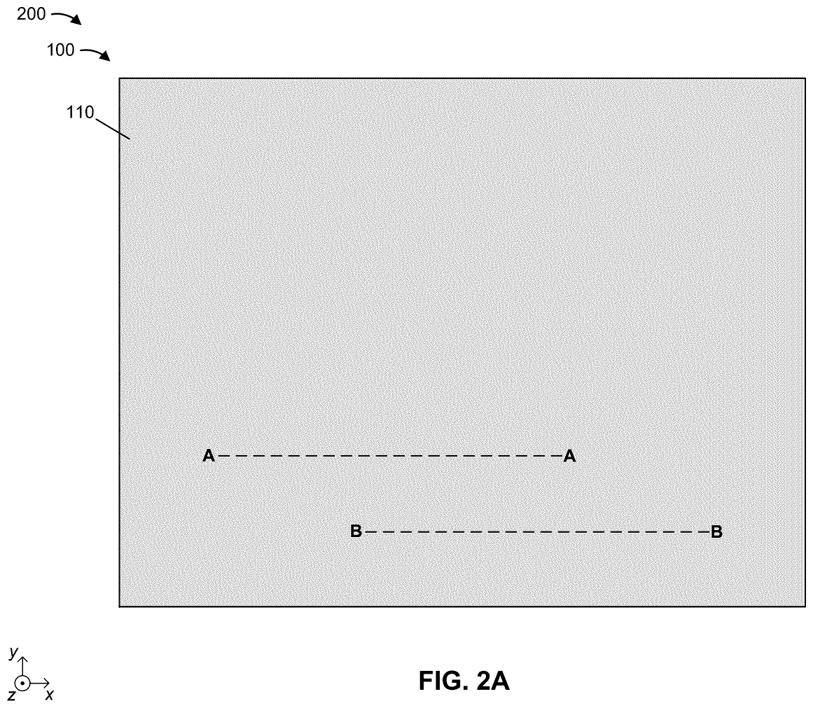

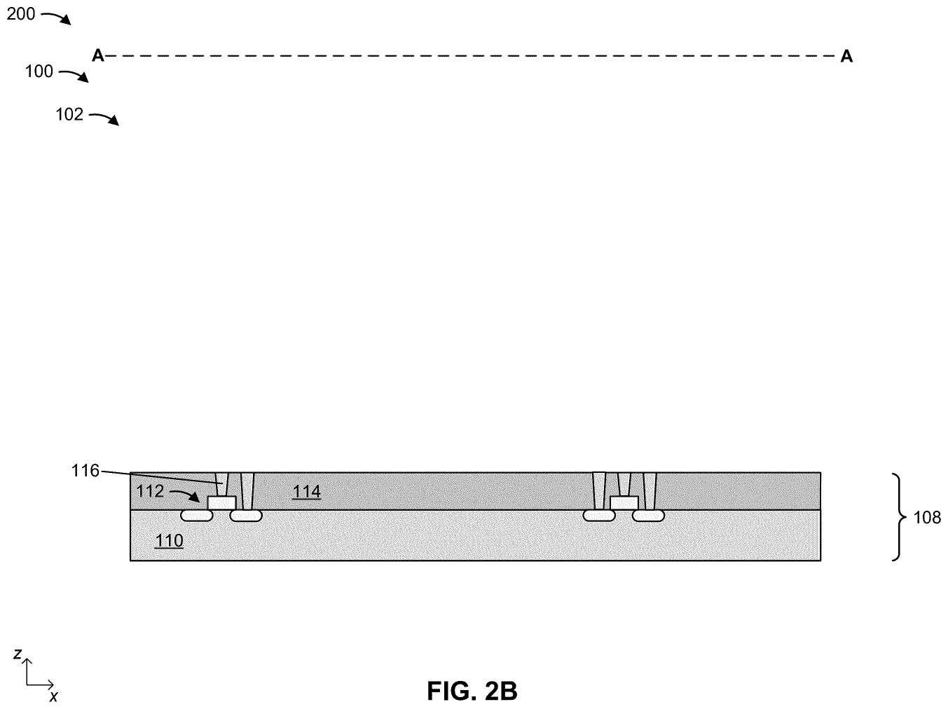

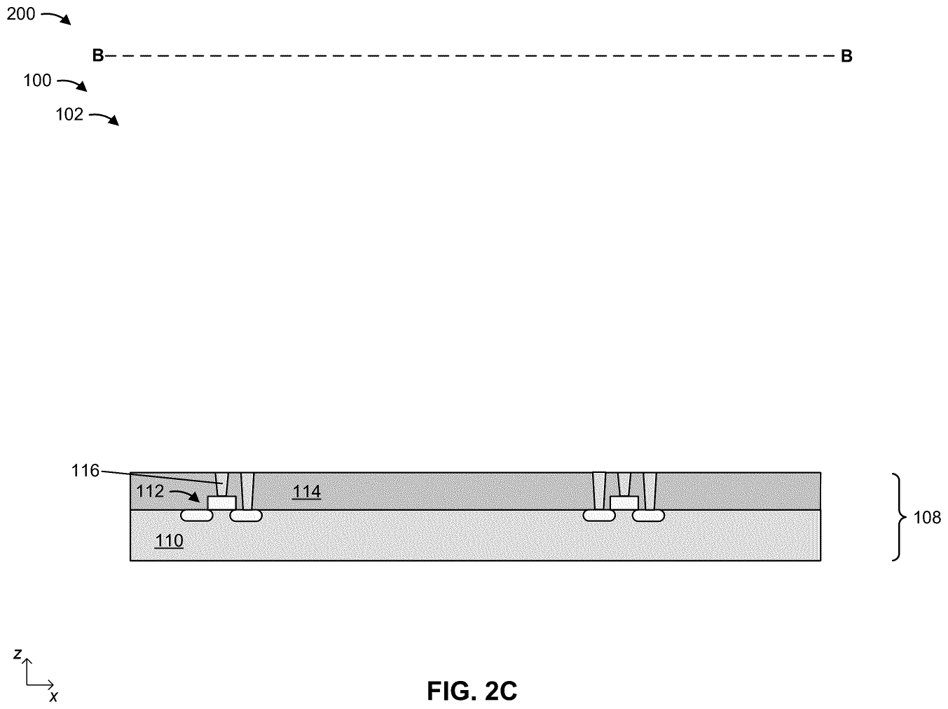

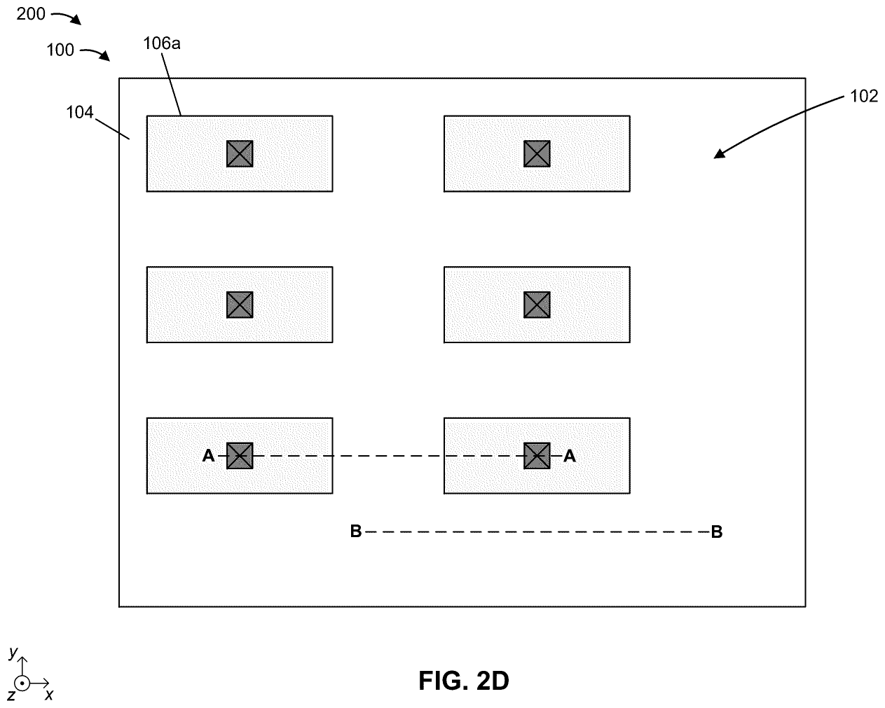

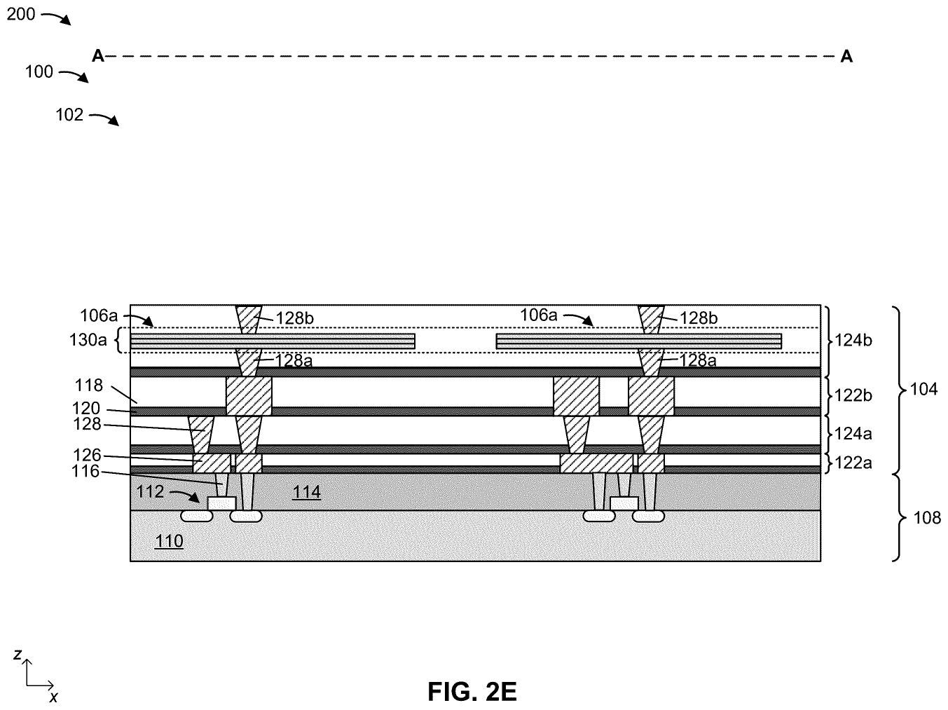

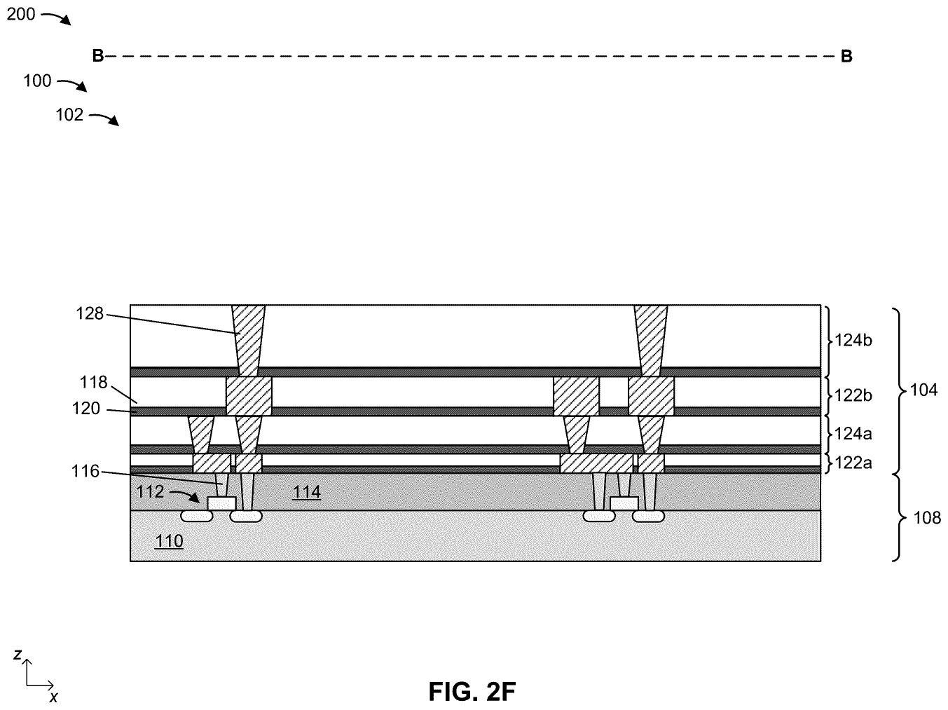

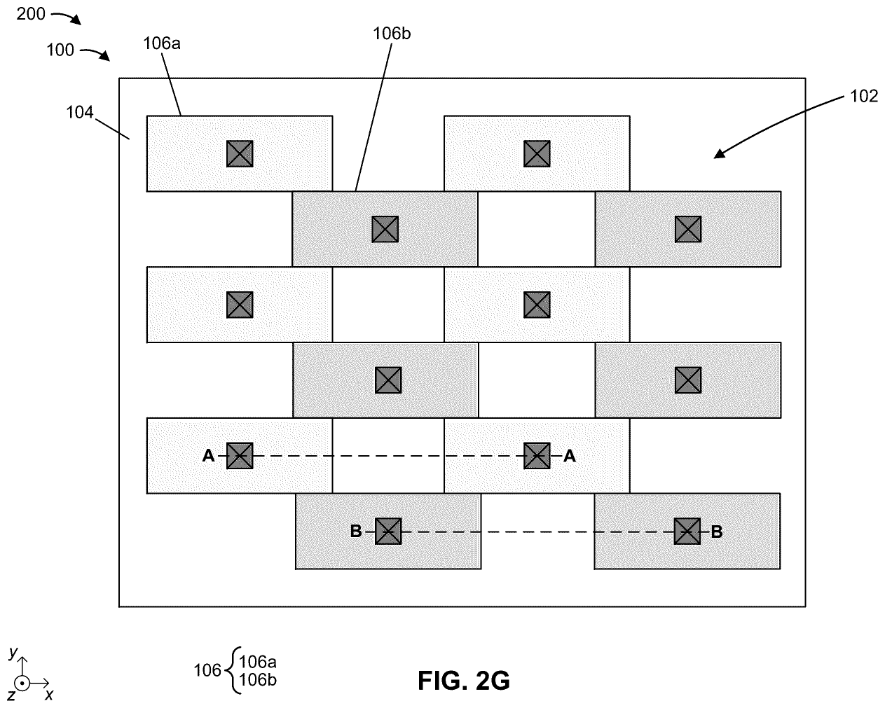

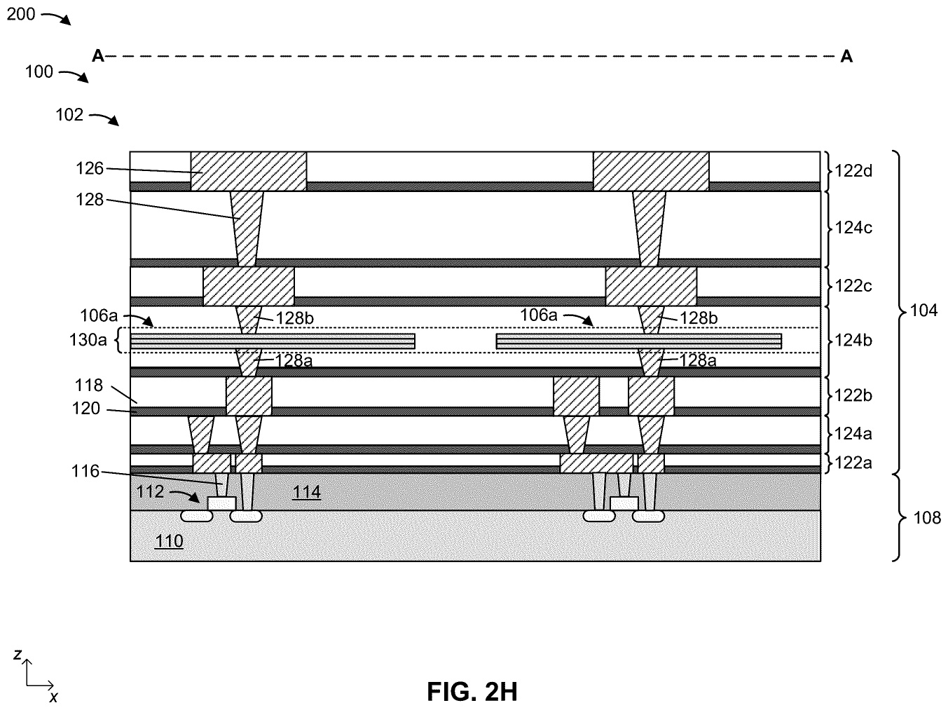

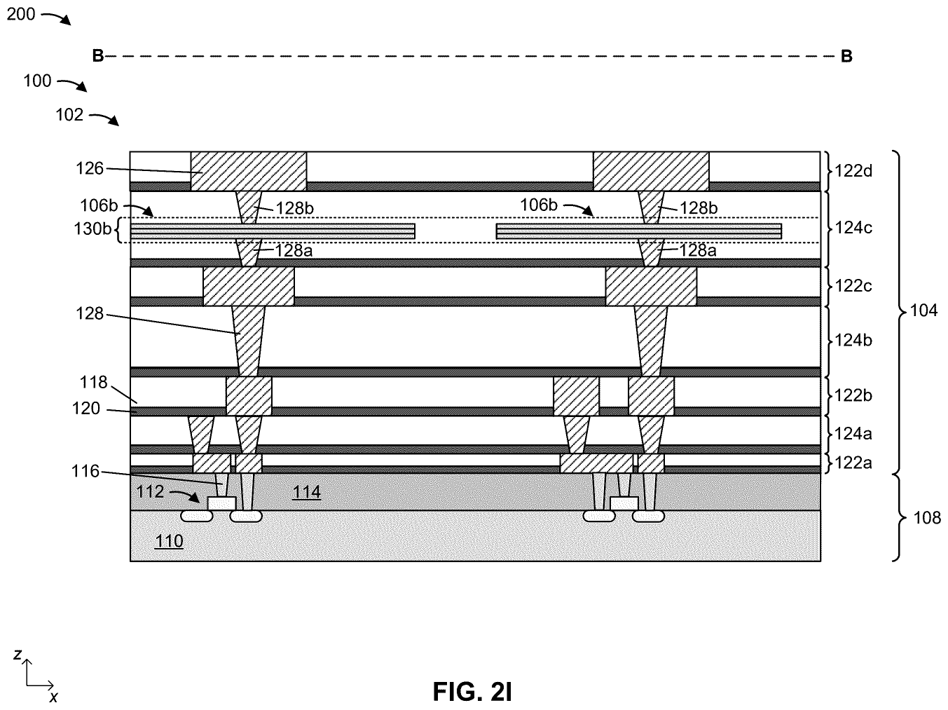

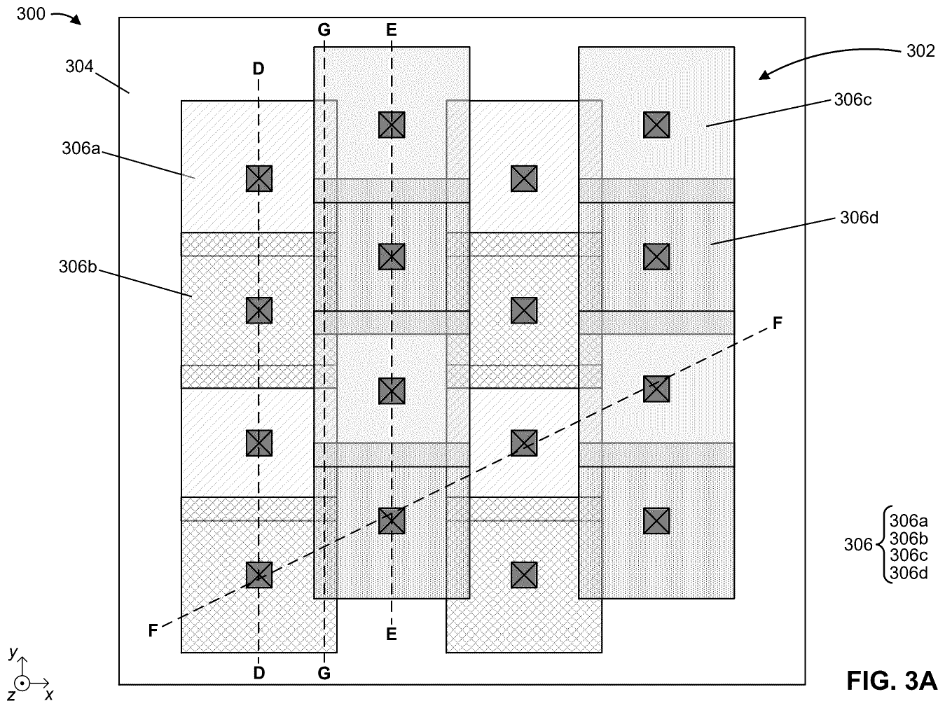

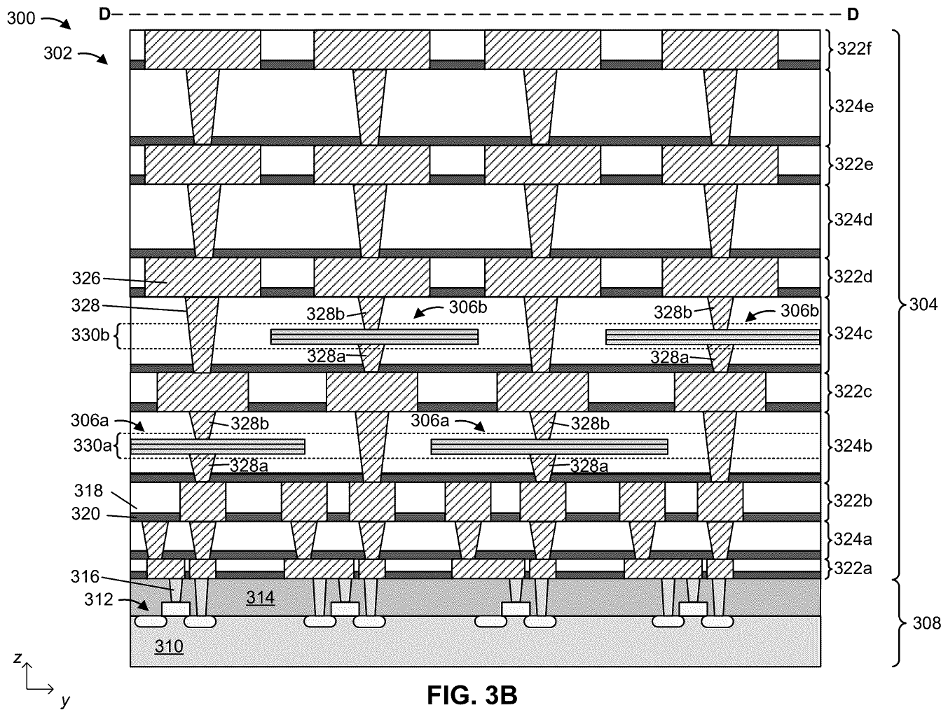

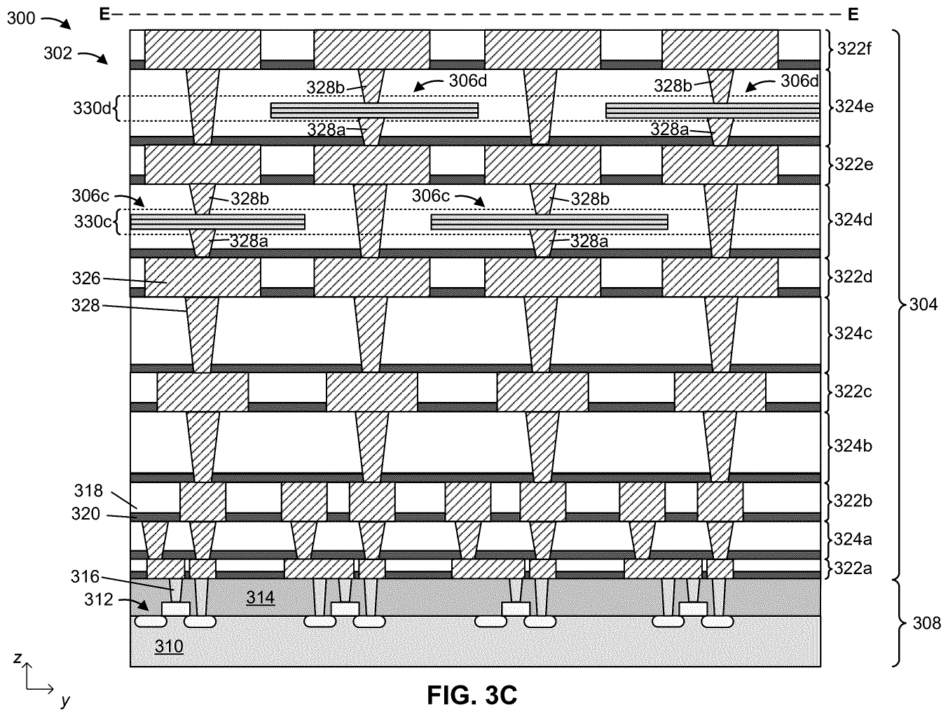

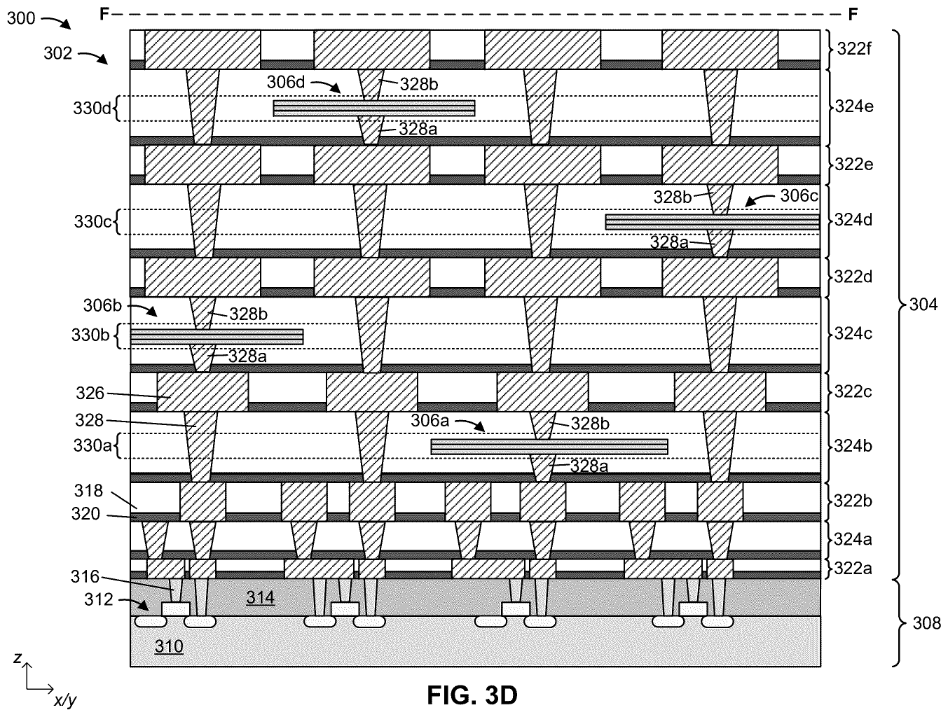

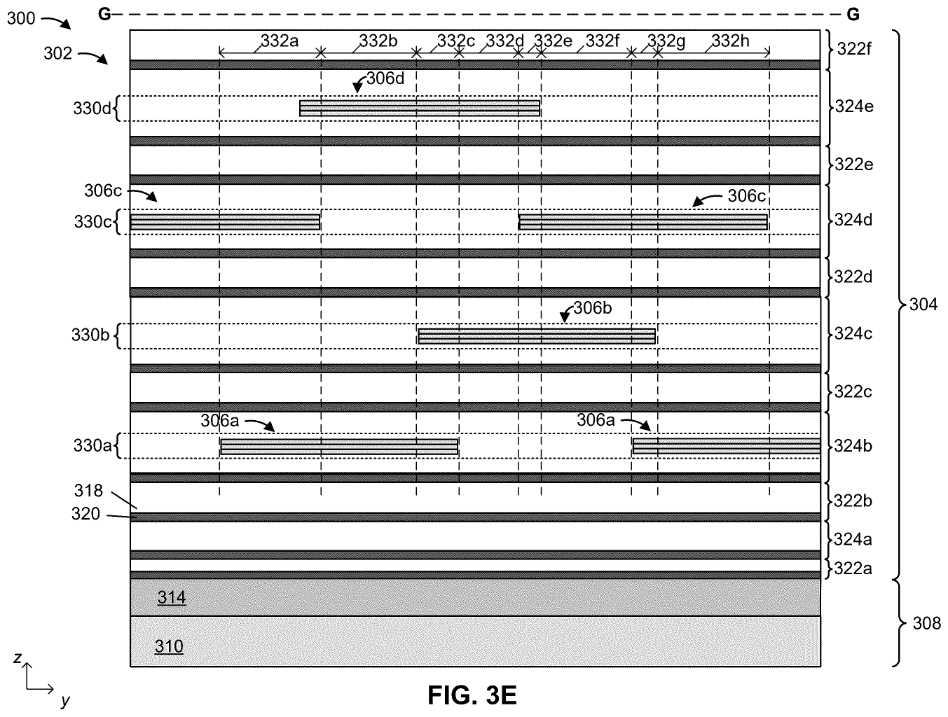

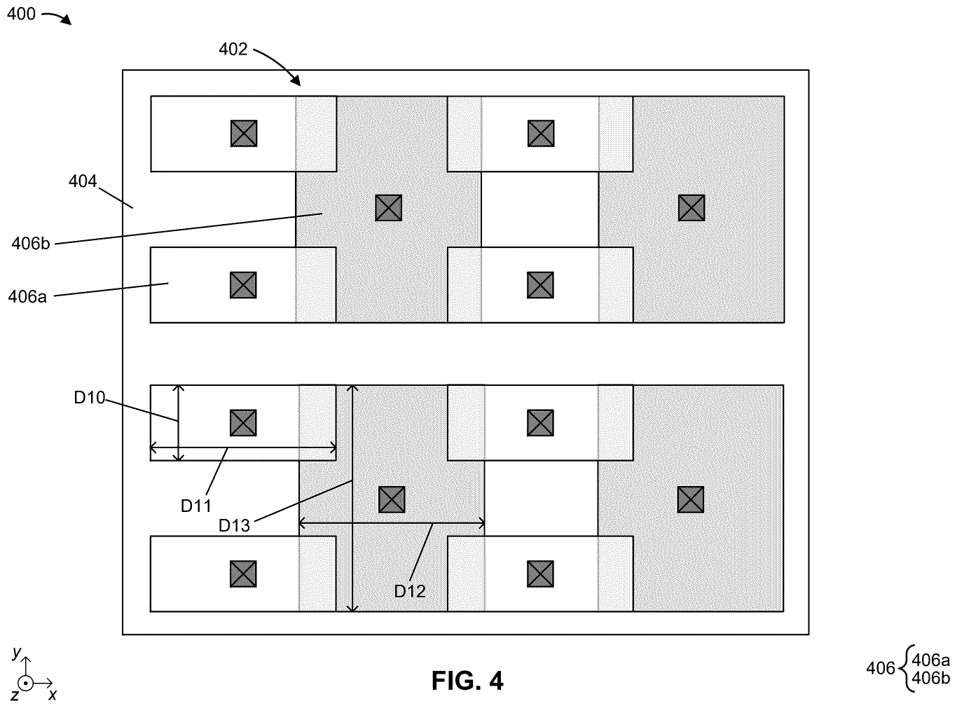

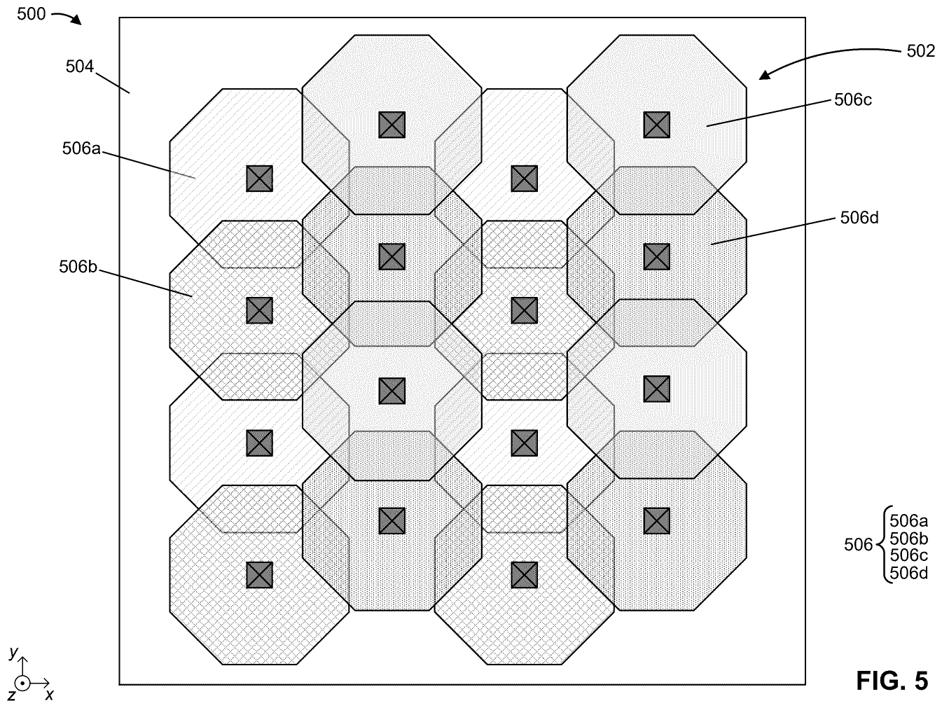

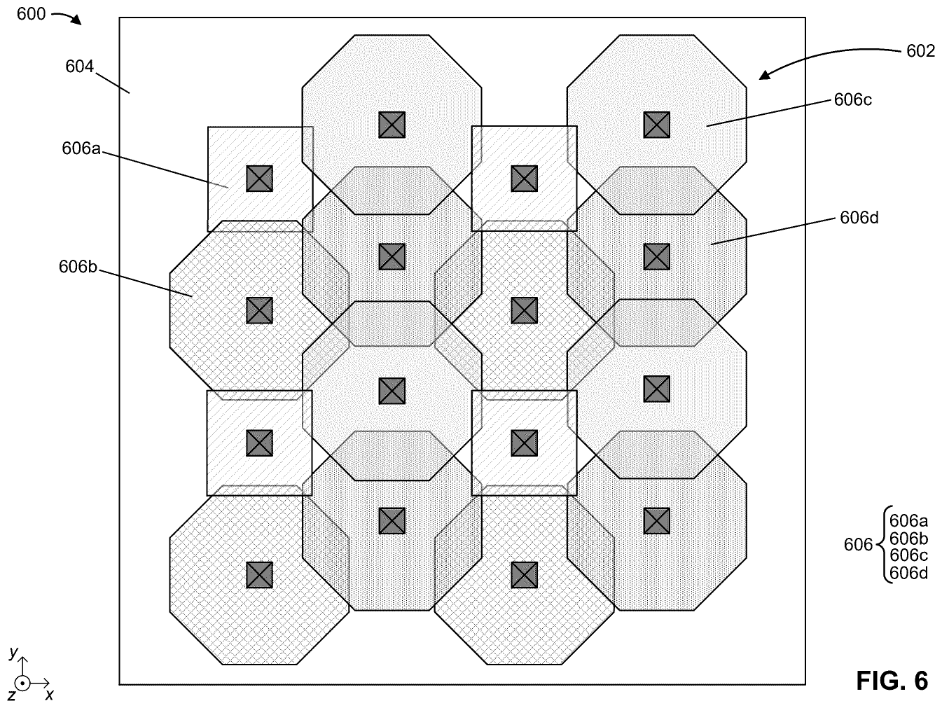

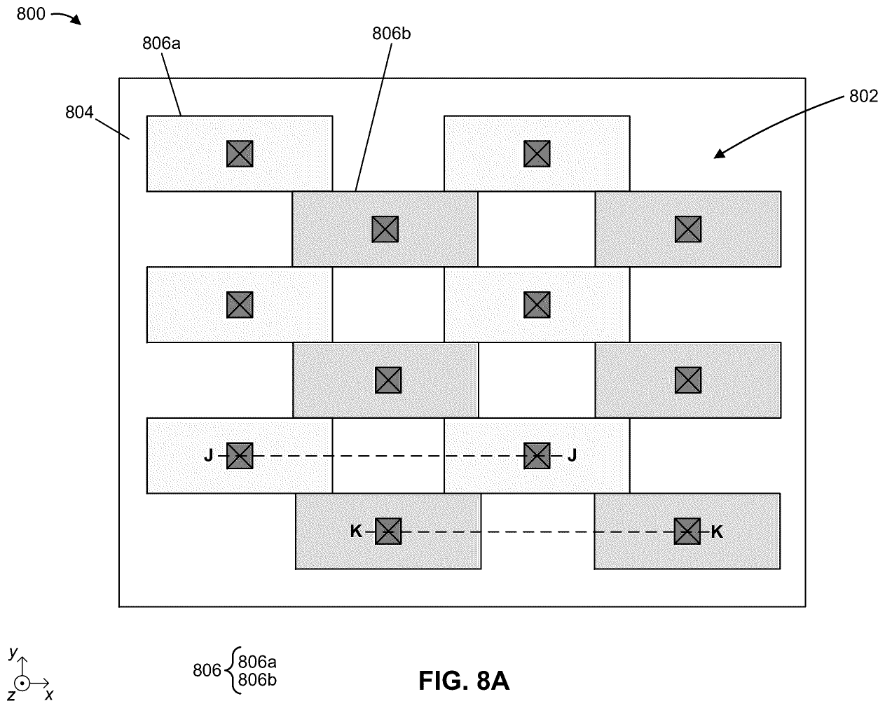

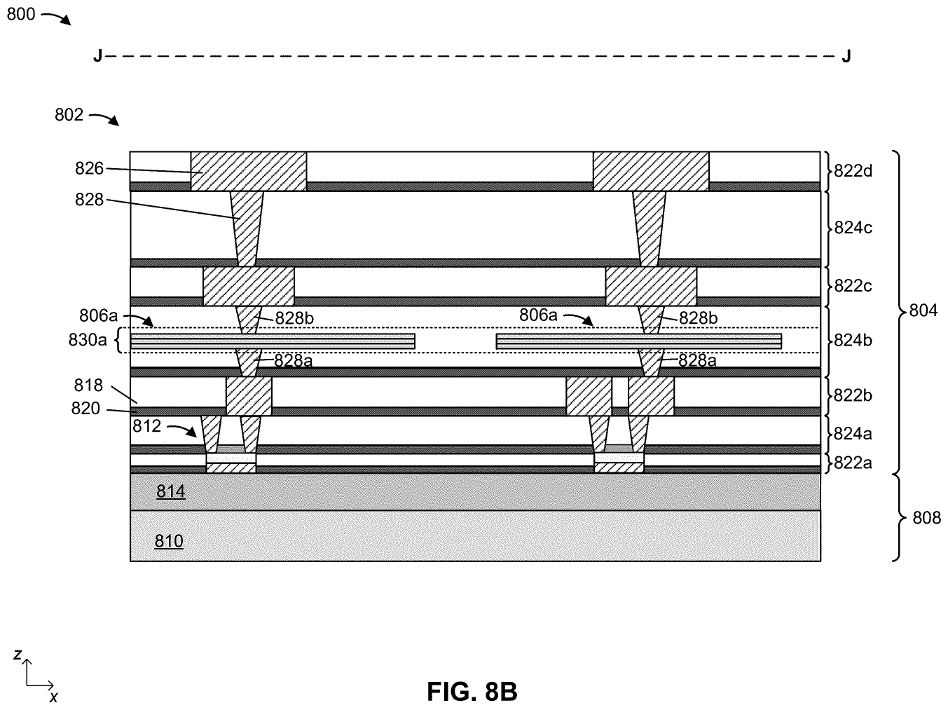

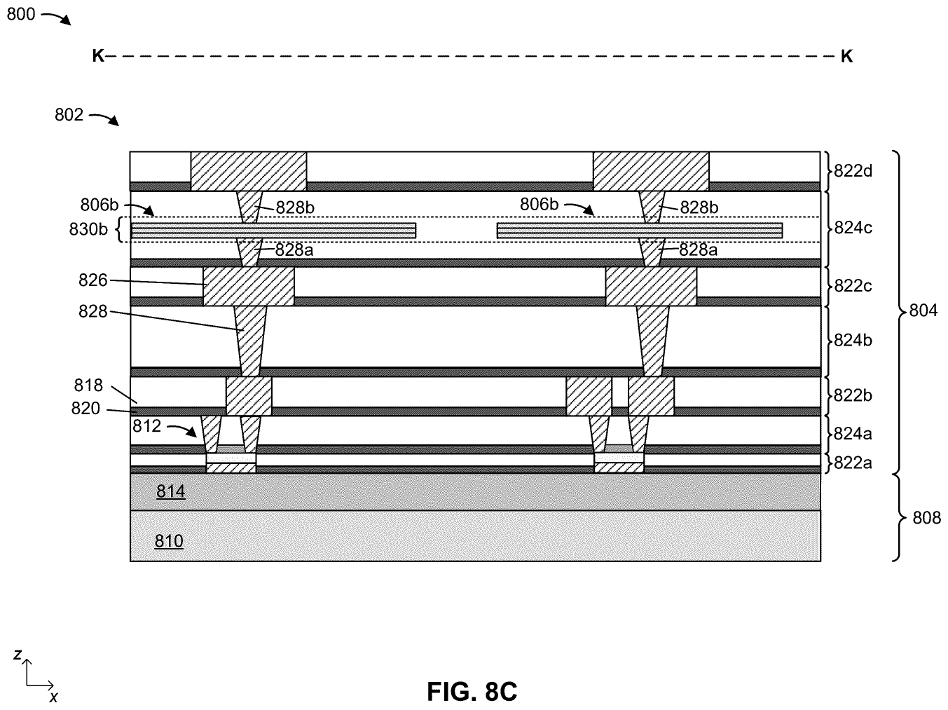

FIGS. 2A-2I are diagrams of an example implementation 200 of forming a semiconductor device described herein. While the processing operations of the example implementation 200 are illustrated and described in connection with forming the semiconductor device 100 described herein, the processing operations of the example implementation 200 may be performed to form another semiconductor device described herein, such as a semiconductor device 300 of FIGS. 3A-3E, a semiconductor device 400 of FIG. 4, a semiconductor device 500 of FIG. 5, a semiconductor device 600 of FIG. 6, a semiconductor device 700 of FIGS. 7A-7C, a semiconductor device 800 of FIGS. 8A-8C, and/or another semiconductor device. In some implementations, one or more of the semiconductor processing operations described in connection with FIGS. 2A-2I may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 2A, the substrate 110 is provided. The substrate 110 may be provided in the form of a semiconductor wafer such as a silicon (Si) wafer may be provided as an SOI wafer, and/or another type of semiconductor work piece.

As shown in FIGS. 2B and 2C, the integrated circuit devices 112 may be formed in and/or on the substrate 110 in the device layer 108 of the semiconductor device 100. One or more semiconductor processing tools may be used to form one or more portions of the integrated circuit devices 112. For example, a deposition tool may be used to perform various deposition operations to deposit layers and/or structures of the integrated circuit devices 112, and/or to deposit photoresist layers for etching the substrate 110 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 110 and/or portions of the deposited layers to form the integrated circuit devices 112. As another example, a planarization tool may be used to planarize portions of the integrated circuit devices 112. As another example, a plating tool may be used to deposit metal structures and/or layers of the integrated circuit devices 112.

Additionally and/or alternatively, integrated circuit devices may be formed in an interconnect layer of a semiconductor device, such as integrated circuit devices 812 in an interconnect layer 804 of a semiconductor device 800 illustrated and described in connection with FIGS. 8A-8C.

As further in FIGS. 2B and 2C, a deposition tool is used to deposit the dielectric layer 114 over and/or on the substrate 110 and over and/or on the integrated circuit devices 112. A deposition tool may be used to deposit the dielectric layer 114 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 114 after the dielectric layer 114 is deposited.

As further shown in FIGS. 2B and 2C, the contacts 116 of the integrated circuit devices 112 may be formed through the dielectric layer 114. The contacts 116 may be formed in recesses in the dielectric layer 114. In some implementations, a pattern in a photoresist layer is used to etch the dielectric layer 114 to form the recesses. In these implementations, a deposition tool may be used to form the photoresist layer on the dielectric layer 114. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 114 based on a pattern to form the recesses.

A deposition tool may be used to deposit the material of the contacts 116 in the recesses using a CVD technique, a PVD technique, an ALD technique, an electroplating technique, and/or another suitable deposition technique. The material of the contacts 116 may be deposited in one or more deposition operations. In some implementations, a seed layer is first deposited, and the material of the contacts 116 is deposited on the seed layer. In some implementations, a planarization tool is used to perform a planarization operation (e.g., a CMP operation) to planarize the contacts 116 after the contacts 116 are deposited such that the tops of the contacts 116 are approximately co-planar with the top of the dielectric layer 114.

As shown in FIGS. 2D-2F, a first portion of the interconnect layer 104 of the semiconductor device 100 is formed above the dielectric layer 114. One or more deposition tools are used to deposit alternating layers of ILD layers 118 and ESLs 120 in the first portion of the interconnect layer 104 of the semiconductor device 100. In this way, the ILD layers 118 and ESLs 120 may be arranged in the z-direction in the semiconductor device 100. One or more deposition tools may be used to deposit each of the ILD layers 118 and each of the ESLs 120 using a PVD technique, an ALD technique, a CVD technique, an oxidation technique, and/or another suitable deposition technique. In some implementations, a planarization tool may be used to planarize the ILD layers 118 and/or the ESLs 120 after the ILD layers 118 and/or the ESLs 120 are deposited.

As further shown in FIGS. 2E and 2F, a deposition tool, an exposure tool, a developer tool, an etch tool, a planarization tool, a plating tool, and/or another semiconductor processing tool may be used to perform various operations to form the layers 122a and 122b of metallization structures 126 and to form the layers 124a and 124b of interconnect structures 128 in the first portion of the interconnect layer 104 of the semiconductor device 100. The layers 122a and 122b of metallization structures 126 and the layers 124a and 124b of interconnect structures 128 may be included in the ILD layers 118 and/or the ESLs 120.

As further shown in FIGS. 2E and 2F, a deposition tool, an exposure tool, a developer tool, an etch tool, a planarization tool, a plating tool, and/or another semiconductor processing tool may be used to perform various operations to form the memory structures 106a of the memory layer 130a in the interconnect layer 104. As an example, an ESL 120 and an ILD layer 118 may be deposited and then etched to form recesses in the ESL 120 and in the ILD layer 118. The layer 122a of metallization structures 126 (e.g., a metal 0 layer or M0 layer) may be formed in the recesses such that one or more of the metallization structures 126 land on the contacts 116. Another ESL 120 and another ILD layer 118 may be formed on the layer 122a of metallization structures 126 and then etched to form recesses in the ESL 120 and in the ILD layer 118. The layer 124a of interconnect structures 128 (e.g., a via 0 layer or V0 layer) may be formed in the recesses such that one or more of the interconnect structures 128 land on one or more of the metallization structures 126 of the layer 122a.

Another ESL 120 and another ILD layer 118 may be formed on the layer 124a of interconnect structures 128 and then etched to form recesses in the ESL 120 and in the ILD layer 118. The layer 122b of metallization structures 126 (e.g., a metal 1 layer or M1 layer) may be formed in the recesses such that one or more of the metallization structures 126 land on one or more interconnect structures 128 of the layer 124a. Another ESL 120 and a first portion of another ILD layer 118 may be formed on the layer 122b of metallization structures 126 and then etched to form recesses in the ESL 120 and in the first portion of the ILD layer 118. The interconnect structures 128a of the layer 124b (e.g., a via 1 layer or V1 layer) may be formed in the recesses such that one or more of the interconnect structures 128a land on one or more of the metallization structures 126 of the layer 122b. The memory structures 106a of the memory layer 130a may be formed on the interconnect structures 128a and on the first portion of the ILD layer 118. A second portion of the ILD layer 118 may then be formed and then etched to form recesses through the ILD layer 118, including to the memory structures 106a and/or to one or more of the metallization structures 126 in the layer 122b. The interconnect structures 128b and/or the interconnect structures 128 of the layer 124b may be formed in the recesses.

As shown in FIGS. 2G-2I, a second portion of the interconnect layer 104 of the semiconductor device 100 is formed above the first portion of the interconnect layer 104. One or more deposition tools are used to deposit alternating layers of ILD layers 118 and ESLs 120 in the second portion of the interconnect layer 104 of the semiconductor device 100. In this way, the ILD layers 118 and ESLs 120 may be arranged in the z-direction in the semiconductor device 100. One or more deposition tools may be used to deposit each of the ILD layers 118 and each of the ESLs 120 using a PVD technique, an ALD technique, a CVD technique, an oxidation technique, and/or another suitable deposition technique. In some implementations, a planarization tool may be used to planarize the ILD layers 118 and/or the ESLs 120 after the ILD layers 118 and/or the ESLs 120 are deposited.

As further shown in FIGS. 2H and 2I, a deposition tool, an exposure tool, a developer tool, an etch tool, a planarization tool, a plating tool, and/or another semiconductor processing tool may be used to perform various operations to form the layers 122c and 122d of metallization structures 126 and to form the layer 124c of interconnect structures 128 in the second portion of the interconnect layer 104 of the semiconductor device 100. The layers 122c and 122d of metallization structures 126 and the layer 124c of interconnect structures 128 may be included in the ILD layers 118 and/or the ESLs 120.

As further shown in FIGS. 2H and 2I, a deposition tool, an exposure tool, a developer tool, an etch tool, a planarization tool, a plating tool, and/or another semiconductor processing tool may be used to perform various operations to form the memory structures 106b of the memory layer 130b in the interconnect layer 104. As an example, an ESL 120 and an ILD layer 118 may be deposited and then etched to form recesses in the ESL 120 and in the ILD layer 118. The layer 122c of metallization structures 126 (e.g., a metal 2 layer or M2 layer) may be formed in the recesses such that one or more of the metallization structures 126 land on the interconnect structures 128 and/or land on the interconnect structures 128b of the layer 124b.

Another ESL 120 and a first portion of another ILD layer 118 may be formed on the layer 122c of metallization structures 126 and then etched to form recesses in the ESL 120 and in the first portion of the ILD layer 118. The interconnect structures 128a of the layer 124c (e.g., a via 2 layer or V2 layer) may be formed in the recesses such that one or more of the interconnect structures 128a land on one or more of the metallization structures 126 of the layer 122c. The memory structures 106b of the memory layer 130b may be formed on the interconnect structures 128a and on the first portion of the ILD layer 118. A second portion of the ILD layer 118 may then be formed and then etched to form recesses through the ILD layer 118, including to the memory structures 106b and/or to one or more of the metallization structures 126 in the layer 122c. The interconnect structures 128b and/or the interconnect structures 128 of the layer 124c may be formed in the recesses.

Another ESL 120 and another ILD layer 118 may be formed on the layer 124c, including one or more of the interconnect structures 128 and/or one or more of the interconnect structures 128b of the layer 124c. The ESL 120 and the ILD layer 118 may be etched to form recesses in the ESL 120 and in the ILD layer 118. The layer 122d of metallization structures 126 (e.g., a metal 3 layer or M3 layer) may be formed in the recesses such that one or more of the metallization structures 126 land on one or more interconnect structures 128 and/or on one or more interconnect structures 128b of the layer 124c.

As indicated above, FIGS. 2A-2I are provided as an example. Other examples may differ from what is described with regard to FIGS. 2A-2I. The processes described in connection with FIGS. 2D-2I may be performed to form additional memory layers of memory structures to form multiple-layer memory arrays in interconnect layers in the semiconductor devices described herein.

FIGS. 3A-3E are diagrams of an example semiconductor device 300 described herein. As shown in FIGS. 3A-3E, the semiconductor device 300 includes a similar arrangement of layers and/or structures as the semiconductor device 100. For example, the semiconductor device 300 includes a memory array 302 in an interconnect layer 304, the memory array 302 includes a plurality of memory structures 306 in the interconnect layer 304, a device layer 308 is located below the interconnect layer 304 and includes integrated circuit devices 312 in a substrate 310 and a dielectric layer 314 through which contacts 316 of the integrated circuit devices 312 extend. Moreover, the interconnect layer 304 includes a plurality of layers 322a of metallization structures 326 and a plurality of layers 324b of interconnect structures 328 vertically arranged with the layers 322a of metallization structures 326.

However, and as shown in FIGS. 3A-3E, the semiconductor device 300 includes a greater quantity of memory layers in the interconnect layer 104 than the semiconductor device 100. As an example, the semiconductor device 300 includes memory structures 306 that are distributed across four (4) vertically arranged memory layers 330a-330d. The memory layer 330a includes memory structures 306a, the memory layer 330b includes memory structures 306b, the memory layer 330c includes memory structures 306c, and the memory layer 330d includes memory structures 306d. The quantity of memory structures and memory layers illustrated in FIGS. 3A-3E are an example, and other quantities of memory structures and memory layers are within the scope of the present disclosure.

As shown in a top view in FIG. 3A, the memory structures 306a and 306b may be arranged in the same rows in the y-direction in the semiconductor device 100, and the memory structures 306c and 306d may be arranged in the same rows in the y-direction in the semiconductor device 100. However, other top view arrangements for the memory structures 306a-306d are within the scope of the present disclosure. For example, memory structures 306a and 306c may be arranged in the same rows in the y-direction in the semiconductor device 100, and the memory structures 306b and 306d may be arranged in the same rows in the y-direction in the semiconductor device 100. As another example, memory structures 306a and 306d may be arranged in the same rows in the y-direction in the semiconductor device 100, and the memory structures 306b and 306c may be arranged in the same rows in the y-direction in the semiconductor device 100.

As further shown in FIG. 3A, the rows of memory structures 306 may be staggered or offset in the y-direction along the x-direction. For example, a row of memory structures 306a and 306b may be laterally offset in the y-direction relative to an adjacent row of memory structures 306c and 306d. However, in some implementations, the rows of memory structures 306a and 306b and the rows of memory structures 306c and 306d are arranged such that the ends of the rows of memory structures 306a and 306b and ends of the rows of memory structures 306c and 306d are aligned in the y-direction.

As further shown in FIG. 3A, a row of memory structures 306a and 306b and an adjacent row of memory structures 306c and 306d may partially laterally overlap. The row of memory structures 306a and 306b and the adjacent row of memory structures 306c and 306d may partially laterally overlap because the memory structures 306a and 306b are located at different vertical (z-direction) heights in the interconnect layer 304 than the memory structures 306c and 306d. Additionally and/or alternatively, the memory structures 306a in a row may partially laterally overlap with the memory structures 306b in the row because the memory structures 306a and the memory structures 306b in the row are located at different vertical (z-direction) heights in the interconnect layer 304. Additionally and/or alternatively, the memory structures 306c in a row may partially laterally overlap with the memory structures 306d in the adjacent row because the memory structures 306c and the memory structures 306d in the adjacent row are located at different vertical (z-direction) heights in the interconnect layer 304. In some implementations, the amount of overlap between memory structures 306 in the memory array 302 is greater than 0 nanometers and less than or approximately equal to 50 nanometers. However, other values and ranges are within the scope of the present disclosure.

FIG. 3B illustrates a cross-section view of the semiconductor device 300 along the line D-D in FIG. 3A. Thus, the cross-section view in FIG. 3B is in the y-z plane in the semiconductor device 300, and is across a row of memory structures 306a and 306b. As shown in FIG. 3B, the interconnect layer 304 includes a vertical (z-direction) arrangement ILD layers 318 and ESLs 320, and a vertical (z-direction) arrangement of layers 322a-322f of metallization structures 326 and layers of 324a-324e of interconnect structures 328. The quantities and arrangements of ILD layers 318, ESLs 320, layers 322a-322f of metallization structures 326, and layers of 324a-324e of interconnect structures 328 is an example, and other quantities and arrangements are within the scope of the present disclosure.

As further shown in FIG. 3B, the memory structures 306a may be included in a memory layer 330a in the interconnect layer 304, and the memory structures 306b may be included in a memory layer 330b in the interconnect layer 304. The memory layer 330a (and thus, the memory structures 306a included in the memory layer 330a) is located at a first vertical (z-direction) height in the interconnect layer 304 and in a same ILD layer 318 in the interconnect layer 304, and the memory layer 330b (and thus, the memory structures 306b included in the memory layer 330b) is located at a second vertical (z-direction) height in the interconnect layer 304 and in a same ILD layer 318 in the interconnect layer 304. The first vertical (z-direction) height and the second vertical (z-direction) height are different vertical (z-direction) heights such that the memory layer 330b (and thus, the memory structures 306b included in the memory layer 330b) is located above the memory layer 330a (and thus, the memory structures 306a included in the memory layer 330a).

In some implementations, the memory layer 330a (and thus, the memory structures 306a included in the memory layer 330a) is included in a layer of interconnect structures 328, such as the layer 324b as shown in the example in FIG. 3B. However, the memory layer 330a (and thus, the memory structures 306a included in the memory layer 330a) may be included in another layer of interconnect structures 328 in the interconnect layer 304, or may be located in a layer of metallization structures 326 as shown in an example in FIGS. 7A-7C.

In the layer 324b of interconnect structures 328, a memory structure 306a may be electrically coupled and/or physically coupled with interconnect structure 328a at a bottom of the memory structure 306a, and may be electrically coupled and/or physically coupled with interconnect structure 328b at a top of the memory structure 306a. Thus, the interconnect structures 328a and 328b coupled to the memory structure 306a may each vertically span less than the entire vertical (z-direction) height of the layer 324b of interconnect structures 328. The interconnect structures 328a in the layer 324b may be electrically coupled and/or physically coupled with metallization structures 326 in the layer 322b below the layer 324b, and the interconnect structures 328b in the layer 324b may be electrically coupled and/or physically coupled with metallization structures 326 in the layer 322c above the layer 324b.

In some implementations, the memory layer 330b (and thus, the memory structures 306b included in the memory layer 330b) is included in a layer of interconnect structures 328, such as the layer 324c as shown in the example in FIG. 3B. However, the memory layer 330b (and thus, the memory structures 306b included in the memory layer 330b) may be included in another layer of interconnect structures 328 in the interconnect layer 304, or may be located in a layer of metallization structures 326 as shown in an example in FIGS. 7A-7C.

In the layer 324c of interconnect structures 328, a memory structure 306b may be electrically coupled and/or physically coupled with interconnect structure 328a at a bottom of the memory structure 306b, and may be electrically coupled and/or physically coupled with interconnect structure 328b at a top of the memory structure 306b. Thus, the interconnect structures 328a and 328b coupled to the memory structure 306b may each vertically span less than the entire vertical (z-direction) height of the layer 324c of interconnect structures 328. The interconnect structures 328a in the layer 324c may be electrically coupled and/or physically coupled with metallization structures 326 in the layer 322c below the layer 324c, and the interconnect structures 328b in the layer 324c may be electrically coupled and/or physically coupled with metallization structures 326 in the layer 322d above the layer 324c.

FIG. 3C illustrates a cross-section view of the semiconductor device 300 along the line E-E in FIG. 3A. Thus, the cross-section view in FIG. 3C is in the y-z plane in the semiconductor device 300, and is across a row of memory structures 306c and 306d. As shown in FIG. 3C, the memory structures 306c may be included in a memory layer 330c in the interconnect layer 304, and the memory structures 306d may be included in a memory layer 330d in the interconnect layer 304. The memory layer 330c (and thus, the memory structures 306c included in the memory layer 330c) is located at a third vertical (z-direction) height in the interconnect layer 304 and in a same ILD layer 318 in the interconnect layer 304, and the memory layer 330d (and thus, the memory structures 306d included in the memory layer 330d) is located at a fourth vertical (z-direction) height in the interconnect layer 304 and in a same ILD layer 318 in the interconnect layer 304. The third vertical (z-direction) height and the fourth vertical (z-direction) height are different vertical (z-direction) heights such that the memory layer 330c (and thus, the memory structures 306d included in the memory layer 330d) is located above the memory layer 330c (and thus, the memory structures 306c included in the memory layer 330c).

In some implementations, the memory layer 330c (and thus, the memory structures 306c included in the memory layer 330c) is included in a layer of interconnect structures 328, such as the layer 324d as shown in the example in FIG. 3C. However, the memory layer 330c (and thus, the memory structures 306c included in the memory layer 330c) may be included in another layer of interconnect structures 328 in the interconnect layer 304, or may be located in a layer of metallization structures 326 as shown in an example in FIGS. 7A-7C.

In the layer 324d of interconnect structures 328, a memory structure 306c may be electrically coupled and/or physically coupled with interconnect structure 328a at a bottom of the memory structure 306c, and may be electrically coupled and/or physically coupled with interconnect structure 328b at a top of the memory structure 306c. Thus, the interconnect structures 328a and 328b coupled to the memory structure 306c may each vertically span less than the entire vertical (z-direction) height of the layer 324d of interconnect structures 328. The interconnect structures 328a in the layer 324d may be electrically coupled and/or physically coupled with metallization structures 326 in the layer 322d below the layer 324d, and the interconnect structures 328b in the layer 324d may be electrically coupled and/or physically coupled with metallization structures 326 in the layer 322e above the layer 324d.

In some implementations, the memory layer 330d (and thus, the memory structures 306d included in the memory layer 330d) is included in a layer of interconnect structures 328, such as the layer 324e as shown in the example in FIG. 3C. However, the memory layer 330d (and thus, the memory structures 306d included in the memory layer 330d) may be included in another layer of interconnect structures 328 in the interconnect layer 304, or may be located in a layer of metallization structures 326 as shown in an example in FIGS. 7A-7C.

In the layer 324e of interconnect structures 328, a memory structure 306d may be electrically coupled and/or physically coupled with interconnect structure 328a at a bottom of the memory structure 306d, and may be electrically coupled and/or physically coupled with interconnect structure 328b at a top of the memory structure 306d. Thus, the interconnect structures 328a and 328b coupled to the memory structure 306d may each vertically span less than the entire vertical (z-direction) height of the layer 324e of interconnect structures 328. The interconnect structures 328a in the layer 324e may be electrically coupled and/or physically coupled with metallization structures 326 in the layer 322e below the layer 324e, and the interconnect structures 328b in the layer 324e may be electrically coupled and/or physically coupled with metallization structures 326 in the layer 322f above the layer 324e.

FIG. 3D illustrates a cross-section view of the semiconductor device 100 along the line F-F in FIG. 3A. Thus, the cross-section view in FIG. 3D is in an x/y-z plane in the semiconductor device 100, and is across a plurality of rows of memory structures 306. As shown in FIG. 3D, in some implementations, each of the memory structures 306a-306d may be electrically coupled with different signal lines (e.g., different vertical arrangements of metallization structures 326 and interconnect structures 328) in the interconnect layer 304. Moreover, each of the memory structures 306a-306d may be electrically coupled with different integrated circuit devices 312 (e.g., different transistors). This enables each of the memory structures 306a-306d may be electrically coupled with different to be individually addressable and accessed in the memory array 302.

FIG. 3E illustrates a cross-section view of the semiconductor device 300 along the line G-G in FIG. 3A. Thus, the cross-section view in FIG. 3E is in the y-z plane in the semiconductor device 300, and is across an area of overlap between a row of memory structures 306a and 306b and an adjacent row of memory structures 306c and 306d. As shown in FIG. 3E, the first vertical (z-direction) height of the memory layer 330a, the second vertical (z-direction) height of the memory layer 330b, the third vertical (z-direction) height of the memory layer 330c, and the fourth vertical (z-direction) height of the memory layer 330c-330d are different vertical (z-direction) heights in the interconnect layer 304. The memory layer 330b (and thus, the memory structures 306b included in the memory layer 330b) is located above the memory layer 330a (and thus, the memory structures 306a included in the memory layer 330a). The memory layer 330c (and thus, the memory structures 306c included in the memory layer 330c) is located above the memory layer 330a (and thus, the memory structures 306a included in the memory layer 330a) and the memory layer 330b (and thus, the memory structures 306b included in the memory layer 330b). The memory layer 330d (and thus, the memory structures 306d included in the memory layer 330d) is located above the memory layer 330a (and thus, the memory structures 306a included in the memory layer 330a), the memory layer 330b (and thus, the memory structures 306b included in the memory layer 330b), and the memory layer 330c (and thus, the memory structures 306c included in the memory layer 330c).

As further shown in FIG. 3E, the memory structures 306a-306d being located in different vertical (z-direction) memory layers 330a-330d enables various areas of at least partial lateral overlap of the memory structures 306a-306d to occur. For example, an area of overlap 332a may occur where a memory structure 306a, a memory structure 306c, and a memory structure 306d at least partially laterally overlap. As another example, an area of overlap 332b may occur where a memory structure 306a and a memory structure 306d at least partially laterally overlap. As another example, an area of overlap 332c may occur where a memory structure 306a, a memory structure 306b, and a memory structure 306d at least partially laterally overlap. As another example, an area of overlap 332d may occur where a memory structure 306b and a memory structure 306d at least partially laterally overlap. As another example, an area of overlap 332e may occur where a memory structure 306b, a memory structure 306c, and a memory structure 306d at least partially laterally overlap. As another example, an area of overlap 332f may occur where a memory structure 306b and a memory structure 306c at least partially laterally overlap. As another example, an area of overlap 332g may occur where a memory structure 306a, a memory structure 306b, and a memory structure 306c at least partially laterally overlap. As another example, an area of overlap 332h may occur where a memory structure 306a and a memory structure 306c at least partially laterally overlap.

As indicated above, FIGS. 3A-3E are provided as an example. Other examples may differ from what is described with regard to FIGS. 3A-3E.

FIG. 4 is a diagram of an example semiconductor device 400 described herein. As shown in FIG. 4, the semiconductor device 400 includes a similar arrangement of layers and/or structures as the semiconductor device 100. For example, the semiconductor device 400 includes a memory array 402 in an interconnect layer 404, and the memory array 402 includes a plurality of memory structures 406 in the interconnect layer 404. The memory structures 406 include a first plurality of memory structures 406a and a second plurality of memory structures 406b. The memory structures 406a are located at a first vertical (z-direction) height in the interconnect layer 404, and the memory structures 406b are located at a second vertical (z-direction) height in the interconnect layer 404 that is different from the first vertical (z-direction) height. Thus, the memory structures 406a and the memory structures 406-406b are vertically distributed in the memory array 402, in addition to being laterally distributed in the memory array 402.

As further shown in FIG. 4, the memory structures 406a and the memory structures 406b are different sizes. For example, the memory structures 406b may have a larger lateral area than the memory structures 406a. The smaller size of the memory structures 406a may enable the memory structures 406a to operate at faster read and write speeds, and thus may be used for memory applications that benefit from lower read and write latency. The larger size of the memory structures 406b may enable the memory structures 406b to retain information for longer durations, and thus may be used for long-term storage applications.

A memory structure 406a may have a y-direction width (indicated in FIG. 4 as dimension D10) and an x-direction width (indicated in FIG. 4 as dimension D11). A memory structure 406b may have a y-direction width (indicated in FIG. 4 as dimension D12) and an x-direction width (indicated in FIG. 4 as dimension D13). In some implementations, the x-direction width (dimension D13) of a memory structure 406b is greater than the x-direction width (dimension D11) of a memory structure 406a. In some implementations, the x-direction width (dimension D13) of a memory structure 406b and the x-direction width (dimension D11) of a memory structure 406a are approximately a same width.

In some implementations, the y-direction width (dimension D12) of a memory structure 406b is greater than the y-direction width (dimension D10) of a memory structure 406a. The y-direction width (dimension D12) of the memory structures 406b being greater than the y-direction width (dimension D10) of the memory structures 406a may result in a plurality of memory structures 406a at least partially laterally overlapping with the same memory structure 406b on a same side of the memory structure 406b. In some implementations, the amount of overlap between a memory structure 406a and a memory structure 406b is greater than 0 nanometers and less than or approximately equal to 50 nanometers. However, other values and ranges are within the scope of the present disclosure. In some implementations, the y-direction width (dimension D12) of a memory structure 406b and the y-direction width (dimension D10) of a memory structure 406a are approximately a same width.

As indicated above, FIG. 4 is provided as an example. Other examples may differ from what is described with regard to FIG. 4.

FIG. 5 is a diagram of an example semiconductor device 500 described herein. As shown in FIG. 5, the semiconductor device 500 includes a similar arrangement of layers and/or structures as the semiconductor device 300. For example, the semiconductor device 500 includes a memory array 502 in an interconnect layer 504, and the memory array 502 includes a plurality of memory structures 506 in the interconnect layer 504.

The memory structures 506 include a first plurality of memory structures 506a, a second plurality of memory structures 506b, a third plurality of memory structures 506c, and a fourth plurality of memory structures 506d. The memory structures 506a are located at a first vertical (z-direction) height in the interconnect layer 504, the memory structures 506b are located at a second vertical (z-direction) height in the interconnect layer 504, the memory structures 506c are located at a third vertical (z-direction) height in the interconnect layer 504, and the memory structures 506d are located at a fourth vertical (z-direction) height in the interconnect layer 504. The first vertical (z-direction) height in the interconnect layer 504, the second vertical (z-direction) height in the interconnect layer 504, the third vertical (z-direction) height in the interconnect layer 504, and the fourth vertical (z-direction) height in the interconnect layer 504 are different vertical (z-direction) heights in the interconnect layer 504. Thus, the memory structures 506a-506d are vertically distributed in the memory array 502, in addition to being laterally distributed in the memory array 502.

However, and as shown in FIG. 5, the memory structures 506a-506d have a different top view shape than the memory structures 306a-306d. In particular, the memory structures 506a-506d each have an approximate octagonal top view shape. The octagonal top view shape of the memory structures 506a-506d may provide efficiencies in lithographic patterning in some semiconductor devices. However, other top view shapes for the memory structures described herein are within the scope of the present disclosure.

As indicated above, FIG. 5 is provided as an example. Other examples may differ from what is described with regard to FIG. 5.

FIG. 6 is a diagram of an example semiconductor device 600 described herein. As shown in FIG. 6, the semiconductor device 600 includes a similar arrangement of layers and/or structures as the semiconductor device 300. For example, the semiconductor device 600 includes a memory array 602 in an interconnect layer 604, and the memory array 602 includes a plurality of memory structures 606 in the interconnect layer 604.

The memory structures 606 include a first plurality of memory structures 606a, a second plurality of memory structures 606b, a third plurality of memory structures 606c, and a fourth plurality of memory structures 606d. The memory structures 606a are located at a first vertical (z-direction) height in the interconnect layer 604, the memory structures 606b are located at a second vertical (z-direction) height in the interconnect layer 604, the memory structures 606c are located at a third vertical (z-direction) height in the interconnect layer 604, and the memory structures 606d are located at a fourth vertical (z-direction) height in the interconnect layer 504. The first vertical (z-direction) height in the interconnect layer 604, the second vertical (z-direction) height in the interconnect layer 604, the third vertical (z-direction) height in the interconnect layer 604, and the fourth vertical (z-direction) height in the interconnect layer 604 are different vertical (z-direction) heights in the interconnect layer 604. Thus, the memory structures 606a-606d are vertically distributed in the memory array 602, in addition to being laterally distributed in the memory array 602.

However, and as shown in FIG. 6, the memory structures 606a have a different top view shape than the memory structures 606b-606c. In particular, the memory structures 606a each have an approximate square top view shape, and each of the memory structures 606b-606c have an approximate octagonal top view shape. The different top view shapes may be configured to optimize the performance of the memory structures 606a-606d for different memory functions. However, other top view shapes for the memory structures described herein are within the scope of the present disclosure. Moreover, different configurations and arrangements of shapes for the memory structures described herein are within the scope of the present disclosure.

As an example, memory structures 606a may have a first top view shape, the memory structures 606b, may have a second top view shape, the memory structures 606c may have a third top view shape, and the memory structures 606d may have a fourth top view shape. Two or more of the first top view shape, the second top view shape, the third top view shape, and the fourth top view shape may be the same top view shape, and/or two or more of the first top view shape, the second top view shape, the third top view shape, and the fourth top view shape may be different top view shapes.

As another example, the memory structures 606a in a first row in the memory array 602 may have a first top view shape, and the memory structures 606a in a second row in the memory array 602 may have a second top view shape. The first top view shape and the second top view shape may be the same top view shape. Alternatively, the first top view shape and the second top view shape may be different top view shapes. Similarly for the memory structures 606b in different rows, the memory structures 606c in different rows, and/or the memory structures 606d in different rows.

As an example, memory structures 606a may have a first top view area, the memory structures 606b, may have a second top view area, the memory structures 606c may have a third top view area, and the memory structures 606d may have a fourth top view area. Two or more of the first top view area, the second top view area, the third top view area, and the fourth top view area may be approximately the same top view area, and/or two or more of the first top view area, the second top view area, the third top view area, and the fourth top view area may be different top view areas.

As another example, the memory structures 606a in a first row in the memory array 602 may have a first top view area, and the memory structures 606a in a second row in the memory array 602 may have a second top view area. The first top view area and the second top view area may be approximately the same top view area. Alternatively, the first top view area and the second top view area may be different top view areas. Similarly for the memory structures 606b in different rows, the memory structures 606c in different rows, and/or the memory structures 606d in different rows.

As indicated above, FIG. 6 is provided as an example. Other examples may differ from what is described with regard to FIG. 6.

FIGS. 7A-7C are diagrams of an example semiconductor device 700 described herein. As shown in FIGS. 7A-7C, the semiconductor device 700 includes a similar arrangement of layers and/or structures as the semiconductor device 100. For example, the semiconductor device 700 includes a memory array 702 in an interconnect layer 704, the memory array 702 includes a plurality of memory structures 706 in the interconnect layer 704, a device layer 708 is located below the interconnect layer 704 and includes integrated circuit devices 712 in a substrate 710 and a dielectric layer 714 through which contacts 716 of the integrated circuit devices 712 extend. Moreover, the interconnect layer 704 includes a plurality of ILD layers 718, a plurality of ESLs 720, a plurality of layers 722a-722d of metallization structures 726, and a plurality of layers 724a-724c of interconnect structures 728 vertically arranged with the layers 722a-722d of metallization structures 726.

However, and as shown in FIGS. 7A-7C, the memory layer 730a of memory structures 706a and the memory layer 730b of memory structures 706b are included in one or more of the layers 722a-722d of metallization structures 726 of the interconnect layer 704 as opposed to being located in one or more of the layers 724a-724c of interconnect structures 728. For example, and as shown in a cross-section view in FIG. 7B that is along the line H-H in FIG. 7A, the memory layer 730a of memory structures 706a may be included in the layers 722b of metallization structures 726. As another example, and as shown in a cross-section view in FIG. 7C that is along the line I-I in FIG. 7A, the memory layer 730b of memory structures 706b may be included in the layer 722c of metallization structures 726. Metallization structures 726a may be coupled to the bottom of the memory structures 706a and to the bottom of the memory structures 706b, and metallization structures 726b may be coupled to the top of the memory structures 706a and to the top of the memory structures 706b.

Alternatively, the memory layer 730a of memory structures 706a may be included in one of the layers 722a-722d of metallization structures 726 in the interconnect layer 704, and the memory layer 730b of memory structures 706b may be included in one of the layers 724a-724c of interconnect structures 728 in the interconnect layer 704. Alternatively, the memory layer 730a of memory structures 706a may be included in one of the layers 724a-724c of interconnect structures 728 in the interconnect layer 704, and the memory layer 730b of memory structures 706b may be included in one of the layers 722a-722d of metallization structures 726 in the interconnect layer 704.

As indicated above, FIGS. 7A-7C are provided as an example. Other examples may differ from what is described with regard to FIGS. 7A-7C.

FIGS. 8A-8C are diagrams of an example semiconductor device 800 described herein. As shown in FIGS. 8A-8C, the semiconductor device 800 includes a similar arrangement of layers and/or structures as the semiconductor device 100. For example, the semiconductor device 800 includes a memory array 802 in an interconnect layer 804, the memory array 802 includes a plurality of memory structures 806 in the interconnect layer 804, a device layer 808 is located below the interconnect layer 804 and includes a substrate 710-810 and a dielectric layer 814. Moreover, the interconnect layer 804 includes a plurality of ILD layers 818, a plurality of ESLs 820, a plurality of layers 822a-822d of metallization structures 826, and a plurality of layers 824a-824c of interconnect structures 828 vertically arranged with the layers 822a-822d of metallization structures 826.

However, and as shown in FIGS. 8A-8C, the integrated circuit devices 812 and the associated contacts are located in the interconnect layer 804 as opposed to being located in the substrate 810 of the device layer 808. Thus, and as shown in a cross-section view in FIG. 8B along the line J-J in FIG. 8A and in a cross-section view in FIG. 8C along the line K-K in FIG. 8A, the integrated circuit devices 812 electrically coupled to the memory structures 806 (including the memory structures 806a in the memory layer 830a and the memory structures 806b included in the memory layer 830b) are back end transistor structures. A backend transistor structure channel layer, a gate dielectric layer between the gate structure and the channel layer, and source/drain electrodes on opposing sides of the channel layer.

The gate electrode and the source/drain electrodes may each include electrically conductive material(s) such as platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), palladium (Pd), copper (Cu), aluminum (Al), ruthenium (Ru), and/or an alloy thereof, among other examples.

The gate dielectric layer may include one or more high-k dielectric materials that have a dielectric constant greater than the dielectric constant of silicon dioxide (SiO₂-approximately 3.9 dielectric constant). Examples of such high-k dielectric materials include metal-oxide materials such as hafnium oxide (HfOₓ such as HfO₂), aluminum oxide (AlₓO_{y} such as Al₂O₃), zirconium oxide (ZrOₓ such as ZrO₂), silicon oxynitride (SiON), an oxide material that includes two or more of hafnium (Hf), titanium (Ti), lanthanum (La), silicon (Si), and/or zirconium (Zr), such as hafnium titanium oxide (HfₓTi_{y}O_{z}), hafnium lanthanum oxide (HfₓLa_{y}O_{z}), hafnium silicon oxide (HfₓSi_{y}O_{z}), and/or hafnium zirconium oxide (HfₓZr_{y}O_{z}), among other examples. Additionally and/or alternatively, the gate dielectric layer may include a silicon oxide (SiOₓ such as SiO₂) and/or a low-k dielectric layer.

The channel layer may include an oxide-semiconductor material. Thus, the backend transistors (e.g., the integrated circuit devices 812) may be oxide-semiconductor field effect transistors (OSFETs). In some implementations, the oxide-semiconductor material includes an n-type oxide-semiconductor material such as tin dioxide (SnO₂), indium gallium zinc oxide (InGaZnO or IGZO), indium gallium oxide (InGaO or IGO), indium zinc oxide (InZnO or IZO), indium tungsten oxide (InWO or IWO), and/or indium oxide (In₂O₃), among other examples. In some implementations, the oxide-semiconductor material includes a p-type oxide-semiconductor material such as nickel oxide (NiO), copper oxide (Cu₂O), copper aluminum oxide (CuAlO₂), copper gallium oxide (CuGaO₂), copper indium oxide (CuInO₂), strontium copper oxide (SrCu₂O₂), and/or tin oxide (SnO), among other examples.

As indicated above, FIGS. 8A-8C are provided as an example. Other examples may differ from what is described with regard to FIGS. 8A-8C.

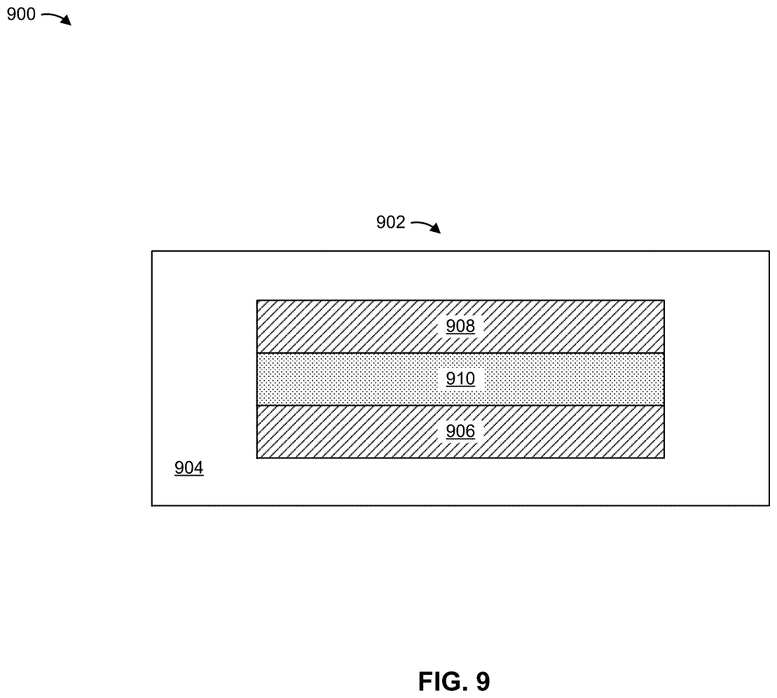

FIG. 9 is a diagram of an example implementation 900 of a memory structure 902 described herein. In some implementations, one or more of the memory structures 106 (including the memory structures 106a and/or 106b), the memory structures 306 (including the memory structures 306a, 306b, 306c, and/or 306d), the memory structures 406 (including the memory structures 406a and/or 406b), the memory structures 506 (including the memory structures 506a, 506b, 506c, and/or 506d), the memory structures 606 (including the memory structures 606a, 606b, 606c, and/or 606d), the memory structures 706 (including the memory structures 706a and/or 706b), and/or the memory structures 806 (including the memory structures 806a and/or 806b) may be implemented as a memory structure 902.

As shown in FIG. 9, the memory structure 902 may be included in a dielectric layer 904, which may correspond to one or more of an ILD layer 118, an ILD layer 318, an ILD layer 718, and/or an ILD layer 818, among other examples. The memory structure 902 may include a bottom electrode 906, a top electrode 908, and a data storage layer 910 sandwiched between the bottom electrode 906 and the top electrode 908. Electrical inputs (e.g., voltages, currents) may be applied to the data storage layer 910 through the bottom electrode 906 and the top electrode 908 to selectively modify one or more properties of the data storage layer 910 to program (or write data to) or erase a logical value stored in the data storage layer 910.

The bottom electrode 906 and/or the top electrode 908 may each include one or more electrically conductive materials, such as tantalum nitride (TaN), titanium nitride (TiN), tungsten (W), aluminum (Al), ruthenium (Ru), cobalt (Co), copper (Cu), platinum (Pt), chromium (Cr), beryllium (Be), antimony (Sb), iridium (Ir), molybdenum (Mo), osmium (Os), thorium (Th), vanadium (V), and/or an alloy thereof, among other examples.

In some implementations, the memory structure 902 is an RRAM structure, and the data storage layer 910 includes an insulator material having non-volatile electrical resistance. In other words, the electrical resistance of the data storage layer 910 may be configured in various persistent states of electrical resistance. Such materials may include hafnium oxide (HfOₓ such as HfO₂) titanium oxide (TiOₓ such as TiO₂), tantalum oxide (TaₓO_{y} such as Ta₂O₅), nickel oxide (NiO), zinc oxide (ZnO), zinc titanate (ZnₓTiO_{y} such as Zn₂TiO₄), manganese oxide (MnOₓ such as MnO₂), magnesium oxide (MgO), aluminum oxide (AlₓO_{y} such as Al₂O₃), and zirconium dioxide (ZrOₓ such as ZrO₂), among other examples.

In some implementations, the memory structure 902 is an MRAM structure or an MTJ structure, and the data storage layer 910 includes a tunnel barrier layer sandwiched between two ferromagnetic layers. This enables the data storage layer 910 to have non-volatile magnetic polarity. In other words, the data storage layer 910 may be configured in various persistent states of magnetic polarity. The ferromagnetic layers materials may include ferrous materials including a combination of iron (Fe) and one or more of cobalt (Co), boron (B), and/or nickel (Ni), among other examples. The tunnel barrier layer may include magnesium oxide (MgO) and/or another suitable material.

In some implementations, the memory structure 902 is an FeRAM structure or an FTJ structure, and the data storage layer 910 includes a ferroelectric layer to selectively store information based on polarization of the data storage layer 910. Examples of ferroelectric materials for the data storage layer 910 include hafnium oxide (e.g., HfO or HfO₂), a zirconium oxide (e.g., ZrO₂), HfZrO or H₂O (e.g., HfₓZr₁₋ₓO_{y}, where x is from 0 to 1, such as Hf_{0.5}Zr_{0.5}O₂), a hafnium silicon oxide (e.g., HfSiO), a hafnium lanthanum oxide (e.g., HfLaO), aluminum nitride (AlN), aluminum scandium nitride (e.g., AlScN), PBT (e.g., PbZrO₃), PZT (e.g., Pb[ZrₓTi₁₋ₓ]O₃, (0≤x≤1)), PLZT (e.g., Pb₁₋ₓLaₓZr_{1-y}Ti_{y}O₃), barium titanate (e.g., BaTiO₃), lead titanate (e.g., PbTiO₃), lead metaniobate (e.g., PbNb₂O₆), lithium niobate (e.g., LiNbO₃), lithium tantalate (e.g., LiTaO₃), PMN (e.g., PbMg₁₋₃Nb_{2/3}O₃), PST (e.g., PbSc_{1/2}Ta_{1/2}O₃), SBT (e.g., SrBi₂Ta₂O₉), BNT (e.g., Bi_{1/2}Na_{1/2}TiO₃), and/or combinations thereof, among other examples. In some implementations, the ferroelectric material may include dopants such as scandium (Sc), lanthanum (La), calcium (Ca), barium (Ba), yttrium (Y), strontium (Sr), and/or gadolinium (Gd), among other examples.

In some implementations, the memory structure 902 is a capacitor structure of a DRAM cell, and the data storage layer 910 is alternatively implemented by an insulator layer between the bottom electrode 906 and the top electrode 908 to form a metal-insulator-metal (MIM) capacitor. The MIM capacitor may be a thin-film capacitor structure, a deep trench capacitor (DTC) structure, and/or another type of capacitor structure. In some implementations, the insulator layer is a low dielectric constant (low-k) dielectric layer such as silicon oxide (SiOₓ such as SiO₂). In some implementations, the insulator layer may include a high-k dielectric layer such as hafnium oxide (HfOₓ such as HfO₂), lanthanum oxide (LaₓO_{y} such as La₂O₃), and/or zirconium oxide (ZrOₓ such as ZrO₂), among other examples.

As indicated above, FIG. 9 is provided as an example. Other examples may differ from what is described with regard to FIG. 9.

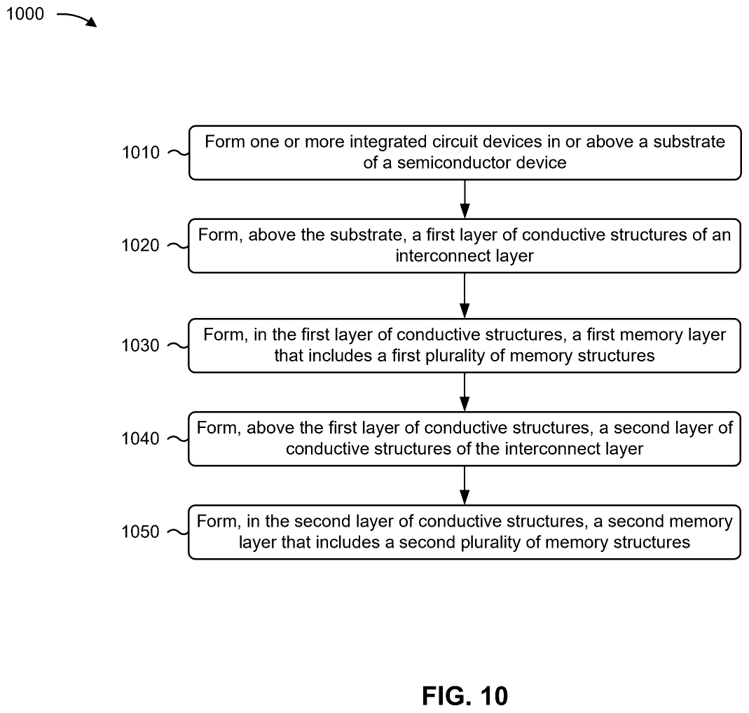

FIG. 10 is a flowchart of an example process 1000 associated with forming a semiconductor device described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming one or more integrated circuit devices in or above a substrate of a semiconductor device (block 1010). For example, one or more semiconductor processing tools may be used to form one or more integrated circuit devices (e.g., integrated circuit devices 112, integrated circuit devices 312, integrated circuit devices 712, integrated circuit devices 812) in or above a substrate (e.g., a substrate 110, a substrate 310, a substrate 710, a substrate 810) of a semiconductor device (e.g., a semiconductor device 100, a semiconductor device 300, a semiconductor device 400, a semiconductor device 500, a semiconductor device 600, a semiconductor device 700, a semiconductor device 800), as described herein.

As further shown in FIG. 10, process 1000 may include forming, above the substrate, a first layer of conductive structures of an interconnect layer (block 1020). For example, one or more semiconductor processing tools may be used to form, above the substrate, a first layer of conductive structures (e.g., a layer 124b of interconnect structures 128, a layer 324b of interconnect structures 328, a layer 324c of interconnect structures 328, a layer 324d of interconnect structures 328, a layer 722b of metallization structures 726, a layer 824b of interconnect structures 828) of an interconnect layer (e.g., an interconnect layer 104, an interconnect layer 304, an interconnect layer 404, an interconnect layer 504, an interconnect layer 604, and an interconnect layer 704, an interconnect layer 804), as described herein.

As further shown in FIG. 10, process 1000 may include forming, in the first layer of conductive structures, a first memory layer that includes a first plurality of memory structures (block 1030). For example, one or more semiconductor processing tools may be used to form, in the first layer of conductive structures, a first memory layer (e.g., a memory layer 130a, a memory layer 330a, a memory layer 330b, a memory layer 330c, a memory layer 730a, a memory layer 830a) that includes a first plurality of memory structures (e.g., memory structures 106a, memory structures 306a, memory structures 306b, memory structures 306c, memory structures 406a, memory structures 506a, memory structures 506b, memory structures 506c, memory structures 606a, memory structures 606b, memory structures 606c, memory structures 706a, memory structures 806a, memory structures 902), as described herein.

As further shown in FIG. 10, process 1000 may include forming, above the first layer of conductive structures, a second layer of conductive structures of the interconnect layer (block 1040). For example, one or more semiconductor processing tools may be used to form, above the first layer of conductive structures, a second layer of conductive structures (e.g., a layer 124c of interconnect structures 128, a layer 324c of interconnect structures 128, a layer 324d of interconnect structures 128, a layer 324e of interconnect structures 128, a layer 722c of metallization structures 126, a layer 824c of interconnect structures 828) of the interconnect layer, as described herein.

As further shown in FIG. 10, process 1000 may include forming, in the second layer of conductive structures, a second memory layer that includes a second plurality of memory structures (block 1050). For example, one or more semiconductor processing tools may be used to form, in the second layer of conductive structures, a second memory layer (e.g., a memory layer 130b, a memory layer 330b, a memory layer 330c, a memory layer 330d, a memory layer 730b, a memory layer 830b) that includes a second plurality of memory structures (e.g., memory structures 106b, memory structures 306b, memory structures 306c, memory structures 306d, memory structures 406b, memory structures 506b, memory structures 506c, memory structures 506d, memory structures 606b, memory structures 606c, memory structures 606d, memory structures 706b, memory structures 806b, memory structures 902), as described herein.

Process 1000 may include additional implementations, such as any single implementation or any combination of implementations described below and/or in connection with one or more other processes described elsewhere herein.

In a first implementation, process 1000 includes forming, above the first layer of conductive structures, a third layer of conductive structures (e.g., a layer 122c of metallization structures 126, a layer 322c of metallization structures 326, a layer 724b of interconnect structures 728, a layer 822c of metallization structures 826) of the interconnect layer, where forming the second layer of conductive structures includes forming the second layer of conductive structures above the third layer of conductive structures.

In a second implementation, alone or in combination with the first implementation, forming the first layer of conductive structures includes forming, prior to formation of the first memory layer, a first set of conductive structures (e.g., interconnect structures 128a, interconnect structures 328a, metallization structures 726a, interconnect structures 828) of the first layer of conductive structures, and forming, after formation of the first memory layer, a second set of conductive structures (e.g., interconnect structures 128, interconnect structures 128b, interconnect structures 328, interconnect structures 328b, metallization structures 726, metallization structures 726b, interconnect structures 828, interconnect structures 828b) of the first layer of conductive structures.

In a third implementation, alone or in combination with one or more of the first and second implementations, forming the first memory layer includes forming the first plurality of memory structures on the first set of conductive structures of the first layer of conductive structures.

In a fourth implementation, alone or in combination with one or more of the first through third implementations, the first plurality of memory structures are each electrically coupled with respective ones of a first set of conductive structures of the first layer of conductive structures, and the second plurality of memory structures are each electrically coupled with respective ones of a second set of conductive structures of the first layer of conductive structures different from the first set of conductive structures.

In a fifth implementation, alone or in combination with one or more of the first through fourth implementations, process 1000 includes forming, above the second layer of conductive structures, a third layer of conductive structures (e.g., a layer 324d of interconnect structures 328) of the interconnect layer, forming, in the third layer of conductive structures, a third memory layer (e.g., a memory layer 330c) that includes a third plurality of memory structures (e.g., memory structures 306c, memory structures 506c, memory structures 606c), forming, above the third layer of conductive structures, a fourth layer of conductive structures (e.g., a layer 324e of interconnect structures 328) of the interconnect layer, and forming, in the second layer of conductive structures, a second memory layer (e.g., a memory layer 330d) that includes a second plurality of memory structures (e.g., memory structures 306d, memory structures 506d, memory structures 606d).

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, memory cells in a memory array in an interconnect layer of a semiconductor device may be distributed across a plurality of vertically arranged layers in the interconnect layer. For example, a first subset of memory cells of the memory array may be included in a first layer of conductive structures of the interconnect layer, and a second subset of memory cells of the memory array may be included in a second layer of conductive structures of the interconnect layer above the first layer of conductive structures. This enables a three-dimensional array of memory cells to be achieved in the interconnect layer of the semiconductor device, which provides a greater amount of lateral area in each metallization layer for the memory cells. This enables a high density of memory cells to be achieved in the memory array without sacrificing the size of the memory cells and/or the spacing between memory cells, which enables more stable operation and a longer operational life for the memory cells.

As described in greater detail above, some implementations described herein provide a semiconductor device. The semiconductor device includes a semiconductor substrate. The semiconductor device includes an interconnect layer above the semiconductor substrate. The semiconductor device includes a memory array in the interconnect layer. The memory array includes a first memory layer including a first plurality of memory structures each located at a first vertical height in the interconnect layer. The memory array includes a second memory layer that includes a second plurality of memory structures each located at a second vertical height in the interconnect layer, where the first vertical height and the second vertical height are different vertical heights.

As described in greater detail above, some implementations described herein provide a semiconductor device. The semiconductor device includes a semiconductor substrate. The semiconductor device includes an interconnect layer above the semiconductor substrate. The interconnect layer includes a plurality of layers of interconnect structures and a plurality of layers of metallization structures vertically alternating with the plurality of layers of interconnect structures. The semiconductor device includes a memory array in the interconnect layer. The memory array includes a first memory layer that includes a first plurality of memory structures each located in a first layer of interconnect structures of the plurality of layers of interconnect structures. The memory array includes a second memory layer that includes a second plurality of memory structures each located in a second layer of interconnect structures of the plurality of layers of interconnect structures. A layer of metallization structures of the plurality of layers of metallization structures is vertically situated between the first layer of interconnect structures and the second layer of interconnect structures.

As described in greater detail above, some implementations described herein provide a method. The method includes forming one or more integrated circuit devices in a substrate of a semiconductor device. The method includes forming, above the substrate, a first layer of conductive structures of an interconnect layer. The method includes forming, in the first layer of conductive structures, a first memory layer that includes a first plurality of memory structures. The method includes forming, above the first layer of conductive structures, a second layer of conductive structures of the interconnect layer. The method includes forming, in the second layer of conductive structures, a second memory layer that includes a second plurality of memory structures.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate;
an interconnect layer above the semiconductor substrate; and
a memory array in the interconnect layer, comprising:
a first memory layer comprising a first plurality of memory structures, each located at a first vertical height in the interconnect layer; and
a second memory layer comprising a second plurality of memory structures, each located at a second vertical height in the interconnect layer,
wherein the first vertical height and the second vertical height are different vertical heights.

2. The semiconductor device of claim 1, wherein the interconnect layer comprises a plurality of layers of conductive structures;
wherein the first memory layer is included in a first layer of conductive structures of the plurality of layers of conductive structures;
wherein the second memory layer is included in a second layer of conductive structures of the plurality of layers of conductive structures; and
wherein the second layer of conductive structures is above the first layer of conductive structures.

3. The semiconductor device of claim 2, wherein a third layer of conductive structures of the plurality of layers of conductive structures is vertically situated between the first layer of conductive structures and the second layer of conductive structures.

4. The semiconductor device of claim 1, wherein a first memory structure of the first plurality of memory structures is laterally offset in a first lateral direction and in a second lateral direction in the semiconductor device, relative to a second memory structure of the second plurality of memory structures.

5. The semiconductor device of claim 1, wherein a first memory structure of the first plurality of memory structures at least partially laterally overlaps a second memory structure of the second plurality of memory structures.

6. The semiconductor device of claim 1, wherein the first plurality of memory structures each have a first top view shape;
wherein the second plurality of memory structures each comprise a second top view shape; and
wherein the first top view shape and the second top view shape are different top view shapes.

7. The semiconductor device of claim 1, wherein the first plurality of memory structures each have a first top view area;
wherein the second plurality of memory structures each comprise a second top view area; and
wherein the second top view area is larger than the first top view area.

8. A semiconductor device, comprising:
a semiconductor substrate;
an interconnect layer, above the semiconductor substrate, comprising:
a plurality of layers of interconnect structures; and
a plurality of layers of metallization structures vertically alternating with the plurality of layers of interconnect structures; and
a memory array in the interconnect layer, comprising:
a first memory layer comprising a first plurality of memory structures, each located in a first layer of interconnect structures of the plurality of layers of interconnect structures; and
a second memory layer comprising a second plurality of memory structures, each located in a second layer of interconnect structures of the plurality of layers of interconnect structures,
wherein a layer of metallization structures of the plurality of layers of metallization structures is vertically situated between the first layer of interconnect structures and the second layer of interconnect structures.

9. The semiconductor device of claim 8, further comprising:
a third memory layer comprising a third plurality of memory structures, each located in a third layer of interconnect structures of the plurality of layers of interconnect structures,
wherein another layer of metallization structures of the plurality of layers of metallization structures is vertically situated between the second layer of interconnect structures and the third layer of interconnect structures.

10. The semiconductor device of claim 9, wherein a first portion of a first memory structure of the first plurality of memory structures partially laterally overlaps a portion of a second memory structure of the second plurality of memory structures; and
wherein a second portion of the first memory structure partially laterally overlaps a portion of a third memory structure of the third plurality of memory structures.

11. The semiconductor device of claim 9, wherein a first portion of a first memory structure of the first plurality of memory structures partially laterally overlaps with a first portion of a second memory structure of the second plurality of memory structures and does not overlap with a third memory structure of the third plurality of memory structures;
wherein a second portion of the first memory structure partially laterally overlaps a first portion of the third memory structure and does not overlap with the second memory structure; and
wherein a third portion of the first memory structure partially laterally overlaps a second portion of the second memory structure and a second portion of the third memory structure.

12. The semiconductor device of claim 8, wherein two or more layers of metallization structures of the plurality of layers of metallization structures are vertically between the first layer of interconnect structures and the second layer of interconnect structures.

13. The semiconductor device of claim 8, wherein a first memory structure of the first plurality of memory structures at least partially laterally overlaps a first side of a second memory structure of the second plurality of memory structures; and
wherein a third memory structure of the first plurality of memory structures at least partially laterally overlaps a second side of the second memory structure opposing the first side.

14. The semiconductor device of claim 8, wherein a first memory structure of the first plurality of memory structures at least partially laterally overlaps a second memory structure of the second plurality of memory structures;
wherein a third memory structure of the first plurality of memory structures at least partially laterally overlaps the second memory structure; and
wherein the first memory structure and the third memory structure both at least partially laterally overlap a same side of the second memory structure.

15. A method, comprising:
forming one or more integrated circuit devices in or above a substrate of a semiconductor device;
forming, above the substrate, a first layer of conductive structures of an interconnect layer;
forming, in the first layer of conductive structures, a first memory layer comprising a first plurality of memory structures;
forming, above the first layer of conductive structures, a second layer of conductive structures of the interconnect layer; and
forming, in the second layer of conductive structures, a second memory layer comprising a second plurality of memory structures.

16. The method of claim 15, further comprising:
forming, above the first layer of conductive structures, a third layer of conductive structures of the interconnect layer,
wherein forming the second layer of conductive structures comprises:
forming the second layer of conductive structures above the third layer of conductive structures.

17. The method of claim 15, wherein forming the first layer of conductive structures comprises:
forming, prior to formation of the first memory layer, a first set of conductive structures of the first layer of conductive structures; and
forming, after formation of the first memory layer, a second set of conductive structures of the first layer of conductive structures.

18. The method of claim 17, wherein forming the first memory layer comprises:
forming the first plurality of memory structures on the first set of conductive structures of the first layer of conductive structures.

19. The method of claim 15, wherein the first plurality of memory structures are each electrically coupled with respective ones of a first set of conductive structures of the first layer of conductive structures; and
wherein the second plurality of memory structures are each electrically coupled with respective ones of a second set of conductive structures of the first layer of conductive structures different from the first set of conductive structures.

20. The method of claim 15, further comprising:
forming, above the second layer of conductive structures, a third layer of conductive structures of the interconnect layer;
forming, in the third layer of conductive structures, a third memory layer comprising a third plurality of memory structures;
forming, above the third layer of conductive structures, a fourth layer of conductive structures of the interconnect layer; and
forming, in the second layer of conductive structures, a second memory layer comprising a second plurality of memory structures.
